(19) United States
(12) Patent Application Publication
(10) Pub. No.: US 2026/0353923 A1
(43) Pub. Date: Nov. 5, 2026

(54) SEMICONDUCTOR DEVICE AND DISPLAY DEVICE

(71) Applicant: SEMICONDUCTOR ENERGY LABORATORY CO., LTD., Atsugi-shi, Kanagawa-ken (JP)

(72) Inventors: Masami JINTYOU, Shimotsuga, Tochigi (JP); Yukinori SHIMA, Tatebayashi, Gunma (JP); Masayoshi DOBASHI, Shimotsuga, Tochigi (JP); Manabu SATO, Oyama, Tochigi (JP); Junichi KOEZUKA, Tochigi, Tochigi (JP); Masataka NAKADA, Tochigi, Tochigi (JP)

(21) Appl. No.: 19/483,670

(22) PCT Filed: May 20, 2024
(86) PCT No.: PCT/IB2024/054869

§ 371 Date: Nov. 12, 2025

(30) Foreign Application Priority Data
May 26, 2023 (JP) 2023-086668

(51) Int. Cl. H10K 59/121

(52) U.S. Cl. CPC H10K 59/1213

(57) ABSTRACT

A transistor that can be miniaturized is provided. A display device that can easily achieve higher resolution is provided. The semiconductor device has a structure which includes an insulating layer having a side surface, and a first transistor and a second transistor each including one of a source electrode and a drain electrode over the insulating layer and the other of the source electrode and the drain electrode below the insulating layer. Semiconductor layers of the first transistor and the second transistor are each in contact with a side surface of the insulating layer. A gate insulating layer shared by the first transistor and the second transistor is in contact with the two semiconductor layers and the side surface of the insulating layer.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display device that includes a semiconductor device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

Miniaturization of transistors has been required. For example, a display device in which a transistor occupies only a small area of a pixel can have downsized pixels, leading to high resolution. In addition, in such a display device, the number of transistors provided per unit area can be increased, that is, a large number of transistors can be arranged in the pixel without increasing the pixel size, so that a correction function or the like can be added to the pixel, for example.

In recent years, the resolution of display panels has been increased. As a device that requires a high-resolution display panel, a device for virtual reality (VR) or augmented reality (AR) has been actively developed in recent years besides a tablet terminal, a smartphone, and a watch-type terminal. For a high-resolution display panel, a light-emitting element such as an organic electroluminescence (EL) element or a light-emitting diode (LED) is mainly used.

Patent Document 1 discloses a high-resolution display device that includes an organic EL device (also referred to as an organic EL element).

### REFERENCE

### Patent Document

### [Patent Document 1] PCT International Publication No. 2016/038508

### SUMMARY OF THE INVENTION

### Problems to be Solved by the Invention

In order to arrange circuit components including transistors with high density, not only miniaturization of the transistors themselves but also layout ingenuity is important. Specifically, in a photolithography method used in a semiconductor manufacturing process, a light exposure limit of a light-exposure apparatus exists, and the minimum feature size of a pattern size of the resist mask, the distance between adjacent patterns, or the like is determined by a light-exposure apparatus, a resist material, or other conditions. In the case where two patterns of different layers overlap with each other, for example, a margin (also referred to as an inclusion margin) is sometimes set in consideration of the positional accuracy of light exposure. The limitation in such a layout is referred to as a design rule in some cases. The design rule might be a large limitation for the case where circuit components are arranged densely.

An object of one embodiment of the present invention is to provide a transistor that can be miniaturized. Another object is to provide a semiconductor device in which transistors can be arranged with high density. Another object is to provide a transistor having favorable electrical characteristics. Another object is to provide a transistor in which a large amount of current can flow. Another object is to provide a transistor having an extremely short channel length. Another object is to provide a transistor that occupies a small area. Another object is to provide a display device that can easily achieve higher resolution. Another object is to provide a transistor, a semiconductor device, or a display device having high reliability.

An object of one embodiment of the present invention is to provide a semiconductor device, a display device, or an electronic device that has a novel structure. An object of one embodiment of the present invention is to at least alleviate at least one of problems of the conventional technique.

The description of these objects does not preclude the existence of other objects. One embodiment of the present invention does not need to achieve all these objects. Other objects can be derived from the description of the specification, the drawings, the claims, and the like.

### MEANS FOR SOLVING THE PROBLEMS

### Means for Solving the Problems

One embodiment of the present invention is a semiconductor device including an insulating layer including a side surface, and a first transistor and a second transistor each including one of a source electrode and a drain electrode over the insulating layer and the other of the source electrode and the drain electrode below the insulating layer. Semiconductor layers of the first transistor and the second transistor are each in contact with the side surface of the insulating layer. A gate insulating layer shared by the first transistor and the second transistor is in contact with the two semiconductor layers and the side surface of the insulating layer.

Another embodiment of the present invention is a semiconductor device including a first transistor, a second transistor, and an insulating layer. The insulating layer includes a first side surface and a second side surface facing the first side surface. The first transistor includes a first conductive layer, a second conductive layer, a first semiconductor layer, a gate insulating layer, and a first gate electrode. The second transistor includes a third conductive layer, a fourth conductive layer, a second semiconductor layer, the gate insulating layer, and a second gate electrode. The first side surface of the insulating layer is positioned over the first conductive layer and the third conductive layer. The second conductive layer and the fourth conductive layer are positioned over the insulating layer. The first semiconductor layer is in contact with the first conductive layer, the second conductive layer, and the first side surface. The second semiconductor layer is in contact with the third conductive layer, the fourth conductive layer, and the first side surface. The gate insulating layer is in contact with the first semiconductor layer, the second semiconductor layer, the first side surface, and the second side surface. The first gate electrode includes a portion overlapping with the first semiconductor layer with the gate insulating layer therebetween, and the second gate electrode includes a portion overlapping with the second semiconductor layer with the gate insulating layer therebetween.

Another embodiment of the present invention is a semiconductor device including a first transistor, a second transistor, and an insulating layer. The insulating layer includes a first side surface and a second side surface facing the first side surface. The first transistor includes a first conductive layer, a second conductive layer, a first semiconductor layer, a gate insulating layer, and a gate electrode. The second transistor includes a third conductive layer, a fourth conductive layer, a second semiconductor layer, the gate insulating layer, and the gate electrode. The first side surface of the insulating layer is positioned over the first conductive layer and the third conductive layer. The second conductive layer and the fourth conductive layer are positioned over the insulating layer. The first semiconductor layer is in contact with the first conductive layer, the second conductive layer, and the first side surface. The second semiconductor layer is in contact with the third conductive layer, the fourth conductive layer, and the first side surface. The gate insulating layer is in contact with the first semiconductor layer, the second semiconductor layer, the first side surface, and the second side surface. The gate electrode includes a portion overlapping with the first semiconductor layer with the gate insulating layer therebetween and a portion overlapping with the second semiconductor layer with the gate insulating layer therebetween.

In any of the above, the first semiconductor layer and the second semiconductor layer each preferably include a first metal oxide. Furthermore, a portion of the first conductive layer that is in contact with the first semiconductor layer and a portion of the third conductive layer that is in contact with the second semiconductor layer preferably include a second metal oxide.

In any of the above, the first semiconductor layer and the second semiconductor layer each preferably include a first metal oxide. Furthermore, a portion of the second conductive layer that is in contact with the first semiconductor layer and a portion of the fourth conductive layer that is in contact with the second semiconductor layer preferably include a third metal oxide.

In any of the above, each of the first semiconductor layer and the second semiconductor layer preferably include a metal oxide. Furthermore, a first insulating film, a second insulating film, and a third insulating film are stacked in this order in the insulating layer. In this case, it is preferable that the first insulating film and the third insulating film include a nitride and the second insulating film include an oxide. It is particularly preferable that the first insulating film and the third insulating film include silicon nitride and the second insulating film include silicon oxide.

In any of the above, an angle formed between the bottom surface of the first insulating layer and the first side surface is preferably greater than or equal to 75° and less than or equal to 90°.

Another embodiment of the present invention is a display device including a first display element, a second display element, and any of the above semiconductor devices. In this case, preferably, the first display element is electrically connected to the first transistor, and the second display element is electrically connected to the second transistor. It is particularly preferable that a plurality of first display elements be included and the first display elements be arranged with a density higher than or equal to 3000 ppi.

### Effect of the Invention

According to one embodiment of the present invention, a transistor that can be miniaturized can be provided. Another embodiment can provide a semiconductor device in which transistors can be arranged with high density. Alternatively, a transistor having favorable electrical characteristics can be provided. Alternatively, a transistor in which a large amount of current can flow can be provided. Alternatively, a transistor having an extremely short channel length can be provided. Alternatively, a transistor that occupies a small area can be provided. Alternatively, a display device that can easily achieve higher resolution can be provided. Alternatively, a transistor, a semiconductor device, or a display device having high reliability can be provided.

According to one embodiment of the present invention, a semiconductor device, a display device, or an electronic device that has a novel structure can be provided. According to one embodiment of the present invention, at least one of problems of the conventional technique can be at least alleviated.

The description of these effects does not preclude the existence of other effects. One embodiment of the present invention does not need to have all these effects. Note that effects other than these can be derived from the description of the specification, the drawings, the claims, and the like.

### BRIEF DESCRIPTION OF THE DRAWINGS

FIG. 1A to FIG. 1C illustrate a structure example of a semiconductor device.

FIG. 2A and FIG. 2B illustrate a structure example of a semiconductor device.

FIG. 3A to FIG. 3C illustrate a structure example of a semiconductor device.

FIG. 4A and FIG. 4B illustrate a structure example of a semiconductor device.

FIG. 5 illustrates a structure example of a semiconductor device.

FIG. 6A and FIG. 6B illustrate a structure example of a semiconductor device.

FIG. 7A to FIG. 7C illustrate structure examples of a semiconductor device.

FIG. 8A and FIG. 8B illustrate a structure example of a semiconductor device.

FIG. 9A and FIG. 9B illustrate a structure example of a semiconductor device.

FIG. 10A to FIG. 10C each illustrate a structure example of a semiconductor device.

FIG. 11A and FIG. 11B each illustrate a structure example of a semiconductor device.

FIG. 12A to FIG. 12C illustrate a structure example of a semiconductor device.

FIG. 13A and FIG. 13B illustrate a structure example of a semiconductor device.

FIG. 14A to FIG. 14C each illustrate a structure example of a semiconductor device.

FIG. 15A and FIG. 15B each illustrate a structure example of a display device.

FIG. 16 illustrates a structure example of a display device.

FIG. 17 illustrates a structure example of a display device.

FIG. 18 illustrates a structure example of a display device.

FIG. 19 illustrates a structure example of a display device.

FIG. 20 illustrates a structure example of a display device.

FIG. 21 illustrates a structure example of a display device.

FIG. 22 illustrates a structure example of a display device.

FIG. 23 illustrates a structure example of a display device.

FIG. 24 illustrates a structure example of a display device.

FIG. 25A to FIG. 25F illustrate a method for manufacturing a display device.

FIG. 26A to FIG. 26D illustrate structure examples of electronic devices.

FIG. 27A to FIG. 27F illustrate structure examples of electronic devices.

FIG. 28A to FIG. 28G illustrate structure examples of electronic devices.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

Note that in each drawing described in this specification, the size, the layer thickness, or the region of each component is exaggerated for clarity in some cases. Thus, the size, the layer thickness, or the region is not limited to the illustrated scale.

Note that in this specification and the like, ordinal numbers such as “first” and “second” are used in order to avoid confusion among components and do not limit the number.

A transistor is a kind of semiconductor elements and can achieve a function of amplifying current or voltage, a switching operation for controlling conduction or non-conduction, and the like. An IGFET (Insulated Gate Field Effect Transistor) and a thin film transistor (TFT) are in the category of a transistor in this specification.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

In this specification and the like, one of a source and a drain of a transistor is referred to as a “first electrode” and the other of the source and the drain is referred to as a “second electrode” in some cases. Note that a gate is also referred to as a “gate electrode”.

In this specification and the like, the term “electrically connected” includes the case where components are connected to each other through an “object having any electric function”. There is no particular limitation on an “object having any electric function” as long as electric signals can be transmitted and received between components that are connected through the object. Examples of the “object having any electric function” include a switching element such as a transistor, a resistor, a coil, and other elements with a variety of functions as well as an electrode or a wiring.

In this specification and the like, the expression “having substantially the same top surface shapes” means that the outlines of stacked layers at least partly overlap with each other. For example, the case of processing an upper layer and a lower layer with the use of the same mask pattern or mask patterns that are partly the same is included. The expression “having substantially the same top surface shapes” also sometimes includes the case where the outlines do not completely overlap with each other; for instance, the edge of the upper layer may be positioned on the inner side or the outer side of the edge of the lower layer.

Note that in this specification and the like, the top surface shape of a component means the shape of the outline of the component in a plan view. A plan view means a view to observe the component from a normal direction of a surface where the component is formed or from a normal direction of a surface of a support (e.g., a substrate) where the component is formed.

Note that the expressions indicating directions such as “over” and “under” are basically used to correspond to the directions of drawings. However, in some cases, the direction indicating “over” or “under” in the specification does not correspond to the direction in the drawings for the purpose of description simplicity or the like. For example, in the description of the stacked order (or the formation order) of a stacked body or the like, even in the case where a surface on which the stacked body is provided (e.g., a formation surface, a support surface, a bonding surface, or a planar surface) is positioned above the stacked body in the drawings, the formation surface side and the opposite direction are expressed using “under” and “over”, respectively, in some cases.

In this specification and the like, the term “film” and the term “layer” can be interchanged with each other. For example, in some cases, the term “insulating layer” can be interchanged with the term “insulating film”.

Note that in this specification, an EL layer refers to a layer that contains at least a light-emitting substance (also referred to as a light-emitting layer) or a stack including the light-emitting layer provided between a pair of electrodes of a light-emitting element.

In this specification and the like, a display panel that is one embodiment of a display device has a function of displaying (outputting) an image or the like on (to) a display surface. Therefore, the display panel is one embodiment of an output device.

In this specification and the like, a structure where a connector such as an FPC (Flexible Printed Circuit) or a TCP (Tape Carrier Package) is attached to a substrate of a display panel, or a structure where an IC (Integrated Circuit) is mounted on the substrate by a COG (Chip On Glass) method or the like is referred to as a display panel module or a display module, or simply as a display panel or the like in some cases.

### Embodiment 1

In this embodiment, a semiconductor device of one embodiment of the present invention and a display device including the semiconductor device will be described.

The semiconductor device of one embodiment of the present invention includes two transistors and an insulating layer. One of the transistors (a first transistor) includes a first semiconductor layer, a gate insulating layer, a first gate electrode, a first electrode functioning as one of a source electrode and a drain electrode, and a second electrode functioning as the other. The other of the transistors (a second transistor) includes a second semiconductor layer, the gate insulating layer, a second gate electrode, a third electrode functioning as one of a source electrode and a drain electrode, and a fourth electrode functioning as the other.

The second electrode is provided above the first electrode. The fourth electrode is provided above the third electrode. Between the first electrode and the second electrode, and between the third electrode and the fourth electrode, an insulating layer functioning as a spacer is provided. The insulating layer includes a side surface (a first side surface) reaching the first electrode and the third electrode. The first semiconductor layer is provided in contact with the first electrode, part of the first side surface, and the second electrode. The second semiconductor layer is provided in contact with the third electrode, another part of the first side surface, and the fourth electrode. The gate insulating layer is provided to cover the first semiconductor layer, the second semiconductor layer, and the first side surface. The first gate electrode includes a portion overlapping with the first semiconductor layer with the gate insulating layer therebetween, and the second gate electrode includes a portion overlapping with the second semiconductor layer with the gate insulating layer therebetween.

The insulating layer can have a structure in which an opening is provided with the first side surface. The shape of the opening preferably extends in one direction, in particular. In this case, the first side surface is one of the side surfaces in the opening that is parallel to the longitudinal direction of the opening, and the other of the side surfaces can be referred to as a second side surface.

Alternatively, the insulating layer can be divided into two by a groove (a slit) extending in one direction. In this case, the first side surface is one of the two side surfaces positioned in the groove and the other can be the second side surface.

The two transistors can be arranged side by side in the direction where the opening or the slit of the insulating layer extends.

Alternatively, the insulating layer may be processed into an isolated pattern with a shape extending in one direction in a plan view. In this case, the first side surface can be part of the side surface that forms the outline of the insulating layer. A portion different from the first side surface can be referred to as a third side surface. The third side surface includes a portion positioned on the opposite side of (back-to-back with) the first side surface of the insulating layer. The first side surface and the third side surface are each preferably the side surface of the insulating layer in the longitudinal direction. In this case, the two transistors can be arranged side by side in the direction where the insulating layer extends.

It can also be said that the semiconductor device of one embodiment of the present invention includes an insulating layer having a side surface and two transistors (a first transistor and a second transistor) each including one of a source electrode and a drain electrode over the insulating layer and the other of the source electrode and the drain electrode below the insulating layer. Furthermore, the two transistors can each be in contact with the side surface of the insulating layer.

In the transistor having the above structure, the source electrode and the drain electrode are positioned at different levels, so that the current flowing through the semiconductor layer flows in the height direction. In other words, the channel length direction can be regarded as having a component of the height direction (the vertical direction); accordingly, the transistor of one embodiment of the present invention can also be referred to as a VFET (Vertical Field Effect Transistor), a vertical transistor, a vertical-channel transistor, and the like. Since the source electrode, the semiconductor, and the drain electrode of the transistor can be provided to overlap with each other, the area occupied by the transistor can be significantly reduced as compared with that occupied by what is called a planar transistor (also referred to as a lateral transistor, an LFET (Lateral FET), or the like) in which a semiconductor is positioned over a flat plane.

A display device employing the above-described vertical transistor can reduce the area occupied by transistors as compared to a display device including a conventional lateral transistor, and accordingly achieves a smaller pixel, more multi-functional pixels, and a higher aperture ratio, for example. Accordingly, the display device can achieve higher resolution, higher reliability, lower power consumption, and the like than a conventional display device.

Here, instead of the first gate electrode and the second gate electrode, a gate electrode shared by the first transistor and the second transistor may be provided. That is, one gate electrode may include a portion covering the first semiconductor layer and a portion covering the second semiconductor layer.

The first transistor and the second transistor may include different gate insulating layers without sharing the same gate insulating layer. For example, when gate insulating layers with different thicknesses, materials, stacked-layer structures, and the like are provided for transistors, transistors with different electrical characteristics can be separately formed.

In one embodiment of the present invention, a plurality of vertical transistors can be arrange along the side surface of the insulating layer with high density. Accordingly, the area occupied by the transistors can be significantly reduced as compared with the case where conventional lateral transistors are employed. Application to a pixel of a display device with such a structure enables the display device to have extremely high resolution.

More specific examples are described below with reference to drawings.

### Structure Example 1

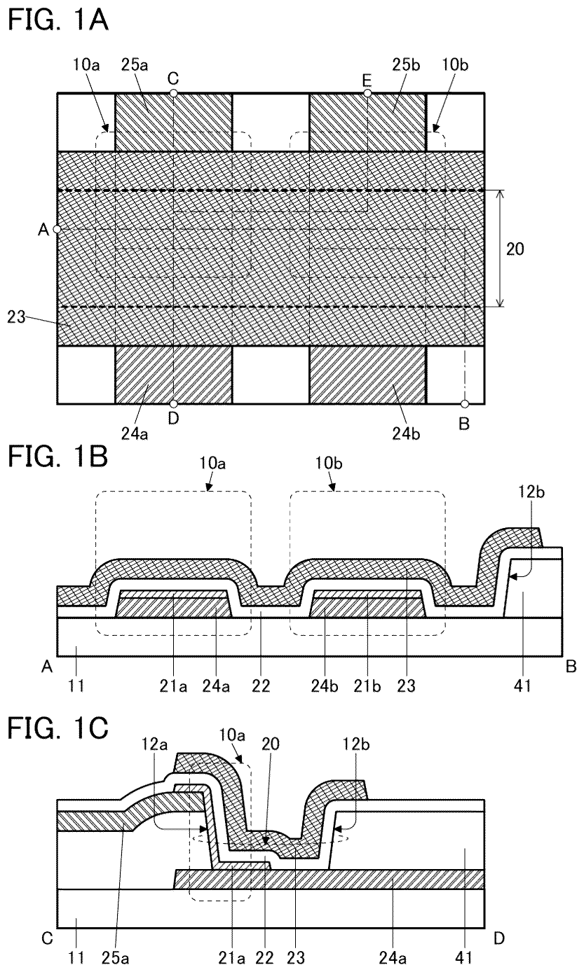

FIG. 1A is a schematic top view of a semiconductor device. FIG. 1B and FIG. 1C are cross-sectional views taken along a cutting line A-B and a cutting line C-D in FIG. 1A, respectively.

The semiconductor device includes a transistor 10a, a transistor 10b, and an insulating layer 41 that are provided over an insulating layer 11 over a substrate (not illustrated). The transistor 10a includes a semiconductor layer 21a, an insulating layer 22, a conductive layer 23, a conductive layer 24a, and a conductive layer 25a. The transistor 10b includes a semiconductor layer 21b, the insulating layer 22, the conductive layer 23, a conductive layer 24b, and a conductive layer 25b. The insulating layer 22 functions as a gate insulating layer of each of the transistors. The conductive layer 23 functions as a gate electrode of each of the transistors. The conductive layer 24a and the conductive layer 24b each function as one of a source electrode and a drain electrode, and the conductive layer 25a and the conductive layer 25b each function as the other.

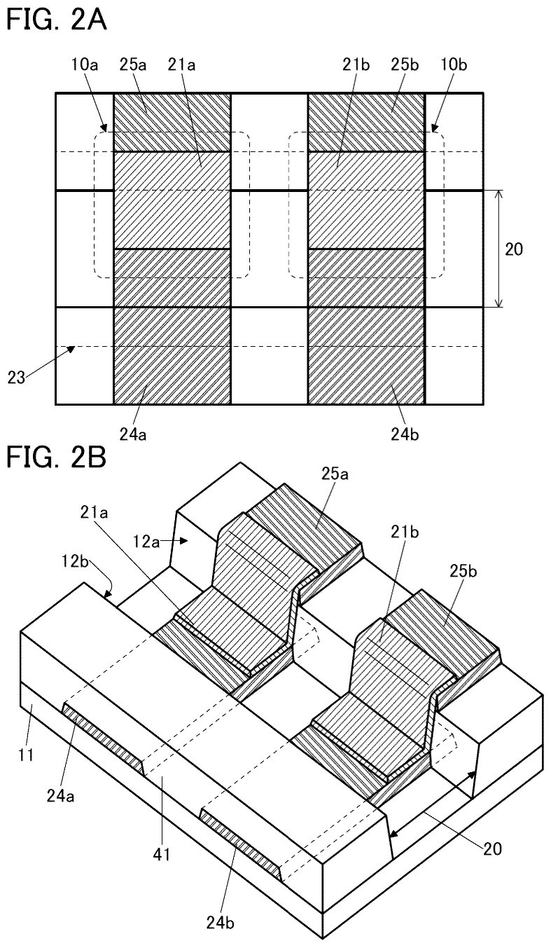

FIG. 2A is a schematic top view in which the outline of the conductive layer 23 is shown by a dashed line. FIG. 2B is a schematic perspective view of the semiconductor device. In FIG. 2B, the conductive layer 23 and the insulating layer 22 are not illustrated.

The conductive layer 24a and the conductive layer 24b are provided over the insulating layer 11, and the insulating layer 41 is provided over the conductive layer 24a and the conductive layer 24b. The insulating layer 41 includes a slit 20 reaching the conductive layer 24a, the conductive layer 24b, and the insulating layer 11.

The slit 20 may have any shape as long as the length in the longitudinal direction is sufficiently longer than (e.g., greater than or equal to 10 times, greater than or equal to 50 times, greater than or equal to 100 times, or greater than or equal to 500 times) the width of the slit or the minimum width of the semiconductor layer 21a. For example, the slit 20 may have a shape with a closed outline in a plan view or a shape in which a pair of substrate edges are connected so that the insulating layer 41 is divided into two.

The insulating layer 41 includes a pair of side surfaces (a side surface 12a and a side surface 12b) that face each other with the slit 20 therebetween. At least the side surface 12a of the pair of side surfaces includes a portion positioned over the conductive layer 24a and the conductive layer 24b. The side surface 12b may also be positioned over the conductive layer 24a and the conductive layer 24b.

The conductive layer 25a and the conductive layer 25b are provided over the insulating layer 41. The conductive layer 25a and the conductive layer 25b may have side surfaces whose top surface shapes are aligned with that of the slit 20 in the plan view. In this case, as illustrated in FIG. 1C, the side surface of the insulating layer 41 positioned in the slit 20 and each of the side surfaces of the conductive layer 25a and the conductive layer 25b (not illustrated) are preferably flat without a step (i.e., the two surfaces are aligned with each other).

Here, an example in which the conductive layer 25a and the conductive layer 25b are positioned over the insulating layer 41 and only on the side surface 12a side is illustrated. In other words, in this example, the conductive layer 25a and the conductive layer 25b are not provided on the opposite side of the slit 20 (on the side surface 12b side).

The insulating layer 11 functions as a base insulating layer of the transistor 10a and the transistor 10b. Note that the transistor 10a and the transistor 10b may be formed directly on the substrate without providing the insulating layer 11 serving as a base insulating layer.

The insulating layer 41 functions as an interlayer insulating layer (spacer) that insulates the conductive layer 24a from the conductive layer 25a, and the conductive layer 24b from the conductive layer 25b.

Note that FIG. 1C illustrates a cross-sectional view of the transistor 10a, and the same applies to the transistor 10b.

The semiconductor layer 21a and the semiconductor layer 21b each include a portion positioned in the slit 20. The semiconductor layer 21a is in contact with a top surface and a side surface of the conductive layer 25a and part of the side surface 12a of the insulating layer 41 and a top surface of the conductive layer 24a in the slit 20. The semiconductor layer 21b is in contact with a top surface and a side surface of the conductive layer 25b and another part of the side surface 12a and a top surface of the conductive layer 24b in the slit 20.

Note that a structure may be employed in which the conductive layer 25a is positioned on the side surface 12a side and the conductive layer 25b is positioned on the side surface 12b side. In this case, the semiconductor layer 21a is in contact with part of the side surface 12a, and the semiconductor layer 21b is in contact with part of the side surface 12b.

Here, as illustrated in FIG. 1C, FIG. 2A, FIG. 2B, and the like, end portions of the semiconductor layer 21a and the semiconductor layer 21b are positioned in the slit 20. More specifically, the end portion of the semiconductor layer 21a is positioned over the conductive layer 24a, and the end portion of the semiconductor layer 21b is positioned over the conductive layer 24b. Thus, the semiconductor layer 21a and the semiconductor layer 21b are not in contact with the side surface 12b of the insulating layer 41. Such a structure can reduce the areas occupied by the transistor 10a and the transistor 10b, which is preferable.

The insulating layer 22 is provided to cover the insulating layer 41, the conductive layer 24a, the conductive layer 24b, the conductive layer 25a, the conductive layer 25b, the semiconductor layer 21a, the semiconductor layer 21b, and the insulating layer 11. A portion of the insulating layer 22 positioned inside the slit 20 is provided along the top surface and a side surface of the semiconductor layer 21a, a side surface of the conductive layer 24a, the top surface and the side surface of the semiconductor layer 21b, a side surface of the conductive layer 24b, and the top surface of the insulating layer 11. The insulating layer 22 includes a portion in contact with the side surface of the insulating layer 41 in the slit 20.

The conductive layer 23 is provided to cover the insulating layer 22. A portion of the conductive layer 23 that overlaps with the semiconductor layer 21a with the insulating layer 22 therebetween functions as a gate electrode of the transistor 10a. A portion of the conductive layer 23 that overlaps with the semiconductor layer 21b with the insulating layer 22 therebetween functions as the gate electrode of the transistor 10b.

The conductive layer 24a and the conductive layer 24b are preferably positioned on the same plane (here, over the insulating layer 11) by processing the same conductive film. Similarly, the conductive layer 25a and the conductive layer 25b are preferably positioned on the same plane (here, over the insulating layer 41) by processing the same conductive film. The conductive layer 24a and the conductive layer 24b are provided to extend in the same direction. The conductive layer 25a and the conductive layer 25b are provided to extend in the same direction.

Moreover, since the channel length of the transistor 10a and the transistor 10b can be precisely controlled by the thickness of the insulating layer 41, a variation in the channel length can be made extremely reduced as compared with that of a planar transistor. Furthermore, by reducing the thickness of the insulating layer 41, a transistor with an extremely short channel length can be manufactured. For example, a transistor with a channel length of less than or equal to 2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm and greater than or equal to 5 nm, greater than or equal to 7 nm, or greater than or equal to 10 nm can be manufactured. Thus, it is possible to obtain a transistor with an extremely short channel length that could not be obtained with the use of a conventional light-exposure apparatus for mass production of flat panel displays (the minimum line width: approximately 2 μm or approximately 1.5 μm, for example). Moreover, it is also possible to obtain a transistor with a channel length less than 10 nm without using an extremely expensive light-exposure apparatus used in the latest LSI technology.

A variety of semiconductor materials can be used for the semiconductor layer 21a and the semiconductor layer 21b; in particular, an oxide semiconductor (OS) including a metal oxide is preferably used. The use of an oxide semiconductor formed under an appropriate condition allows a transistor having both a high on-state current and an extremely low off-state current to be achieved at a low cost. Described below are preferable structure examples of the case where an oxide semiconductor is used for the semiconductor layer 21a and the semiconductor layer 21b unless otherwise specified.

The top surfaces of the conductive layer 24a, the conductive layer 24b, the conductive layer 25a, and the conductive layer 25b are in contact with the semiconductor layer 21a or the semiconductor layer 21b. Hence, in the case where an oxide semiconductor is used for the semiconductor layer 21a and the semiconductor layer 21b, the surfaces of the conductive layer 24a, the conductive layer 24b, the conductive layer 25a, and the conductive layer 25b and the vicinities thereof might be oxidized by the effect of heat or the like generated in a formation step of a semiconductor film to be the semiconductor layer 21a and the semiconductor layer 21b or in a later step, so that an insulating oxide film might be formed between the conductive layers 24a, 24b, 25a, and 25b and the semiconductor layer 21a or the semiconductor layer 21b, increasing the contact resistance. Thus, an oxide conductor including a metal conductive oxide is preferably used at least for the uppermost portions of the conductive layer 24a, the conductive layer 24b, the conductive layer 25a, and the conductive layer 25b (i.e., the portion in contact with the semiconductor layer 21a or the semiconductor layer 21b). This can prevent an increase in the contact resistance due to the oxidation of the surfaces of the conductive layer 24a, the conductive layer 24b, the conductive layer 25a, and the conductive layer 25b. The conductive layer 24a, the conductive layer 24b, the conductive layer 25a, and the conductive layer 25b can also be referred to as an oxide layer, a metal oxide layer, an oxide conductive layer, or the like.

Parts of the conductive layer 24a and the conductive layer 24b can each be used as one of a source wiring and a drain wiring. Parts of the conductive layer 25a and the conductive layer 25b can each be used as the other of the source wiring and the drain wiring. In the case where the conductive layer 24a, the conductive layer 24b, the conductive layer 25a, or the conductive layer 25b is used as a wiring in this manner, they preferably have low electric resistance. Thus, a material having higher conductivity than an oxide conductor, such as a metal, an alloy, or a nitride thereof, is preferably used. It is particularly preferable to have a stacked-layer structure including a layer of the material having high conductivity, where the above-described oxide conductor is used at least for the uppermost portion.

An example of the case having a structure partly different from the above is described below. Note that unless otherwise specified, the above description is referred to for the portions similar to those described above and the description thereof is omitted.

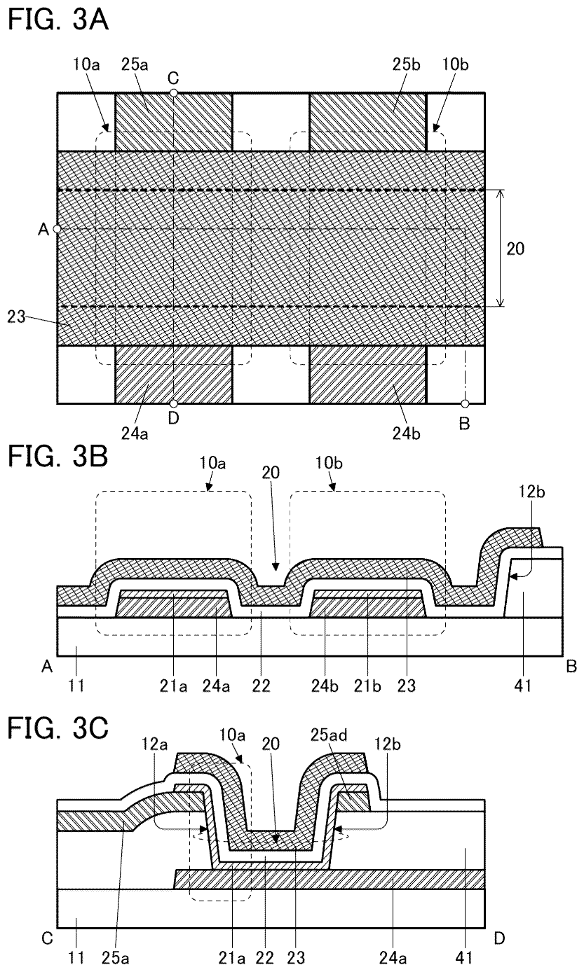

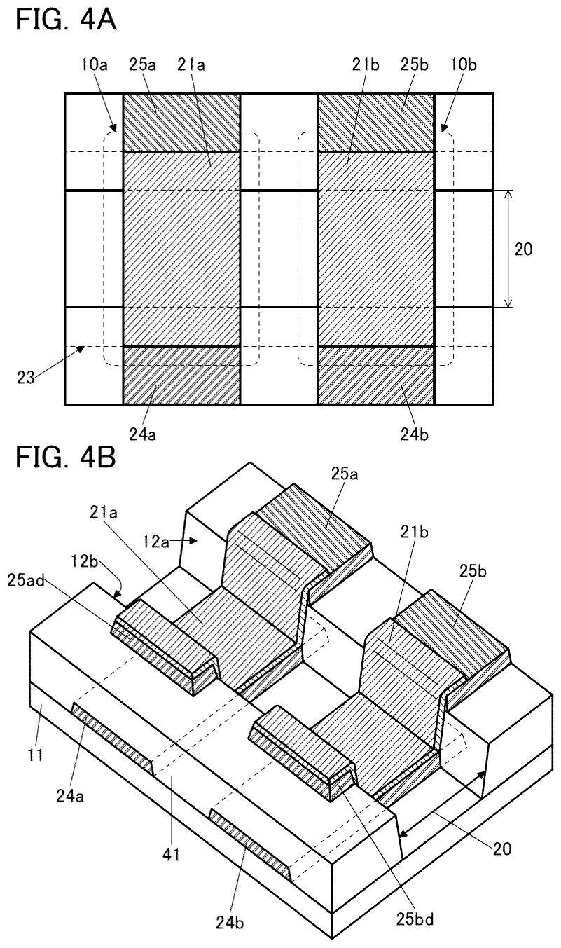

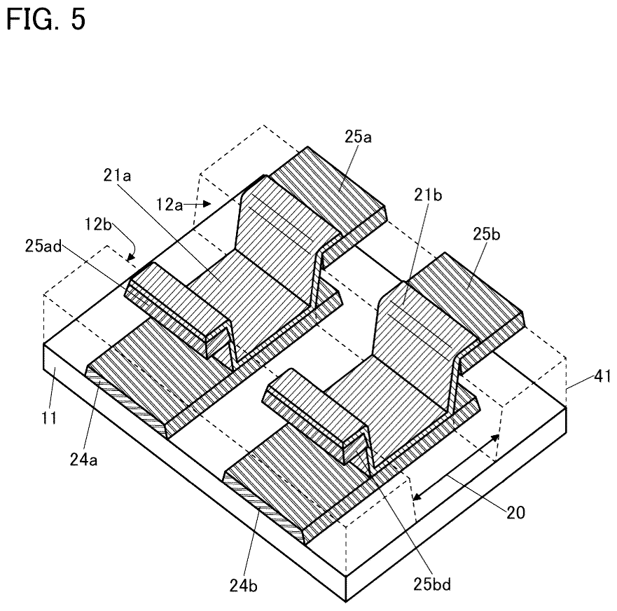

FIG. 3A to FIG. 3C, FIG. 4A, and FIG. 4B illustrate an example of the case where the semiconductor layer 21a and the semiconductor layer 21b are provided also on the side surface 12b of the insulating layer 41. FIG. 5 is a schematic perspective view in which only the outline of the insulating layer 41 in FIG. 4B is indicated by a dashed line.

A conductive layer 25ad and a conductive layer 25bd are provided above the side surface 12b side of the insulating layer 41. The conductive layer 25a and the conductive layer 25b are remnants of the conductive layer 25ad and the conductive layer 25bd, respectively, which have been partially divided during the formation of the slit 20.

The end portions of the semiconductor layer 21a and the semiconductor layer 21b are positioned not in the slit 20 but over the insulating layer 41. Specifically, the semiconductor layer 21a is provided in contact with the side surface 12b of an insulating layer 41b and with a side surface and a top surface of the conductive layer 25ad. Similarly, the semiconductor layer 21b is in contact with the side surface 12b and with a top surface and a side surface of the conductive layer 25bd.

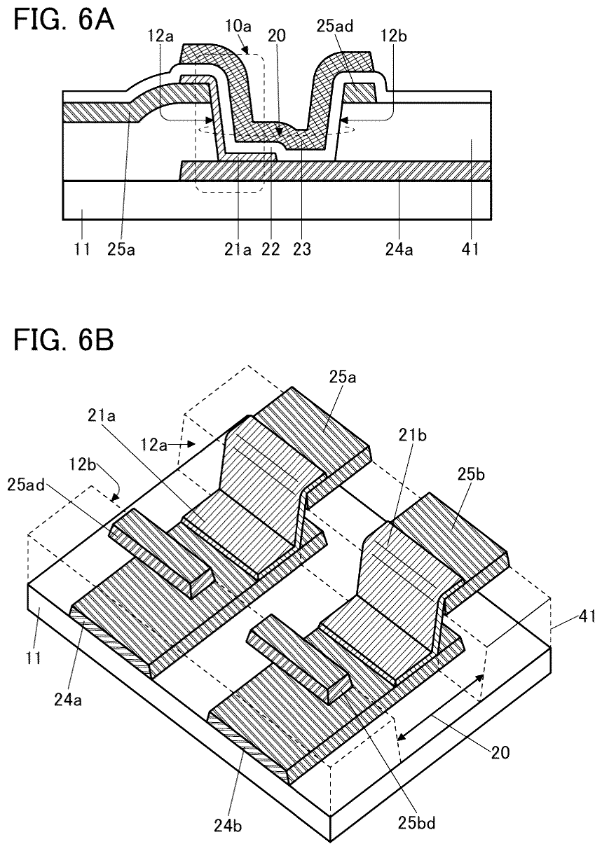

FIG. 6A and FIG. 6B illustrate an example of the case where the conductive layer 25ad and the conductive layer 25bd are included and the end portions of the semiconductor layer 21a and the semiconductor layer 21b are positioned in the slit 20. The conductive layer 25ad and the conductive layer 25bd are not in contact with the semiconductor layer 21a and the semiconductor layer 21b respectively and therefore electrically floating.

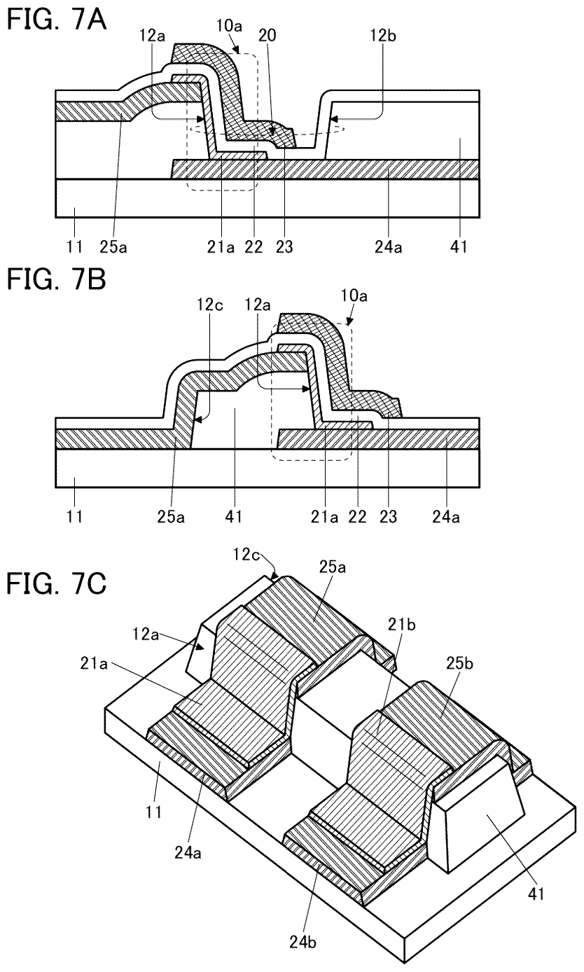

FIG. 7A illustrates an example of the case where an end portion of the conductive layer 23 is provided in the slit 20. In this case, as illustrated in FIG. 7A, the conductive layer 23 preferably covers the end portion of the semiconductor layer 21a in the slit 20. This improves the controllability in controlling the conductivity of the semiconductor layer 21a with a potential applied to the conductive layer 23, which is preferable.

The above four structure examples are examples where the relative positional relationships and shapes of the slit 20, the semiconductor layer 21a, the semiconductor layer 21b, the conductive layer 25a, and the conductive layer 25b are different. Accordingly, they can be formed separately over the same substrate through the same process.

FIG. 7B and FIG. 7C illustrate an example in which the insulating layer 41 has a different shape.

The insulating layer 41 is processed into an isolated pattern in a plan view. The insulating layer 41 has a rectangular outline in the plan view. Note that the shape of the insulating layer 41 is not limited to this and can be a variety of shapes.

The insulating layer 41 includes the side surface 12a and a side surface 12c positioned back-to-back with the side surface 12a. FIG. 7B is a schematic cross-sectional view of a portion including the side surface 12a and the side surface 12c. The transistor 10a and the transistor 10b are provided on the side surface 12a side of the insulating layer 41.

The insulating layer 41 is provided to cover end portions of the conductive layer 24a and the conductive layer 24b. The conductive layer 25a and the conductive layer 25b are provided to cover part of the top surface of the insulating layer 41 and the side surface 12c. The semiconductor layers 21a and 21b are each provided in contact with the side surface 12a.

With such a structure, a plurality of vertical transistors can be arranged side by side on the side surface of the insulating layer 41 having an isolated pattern.

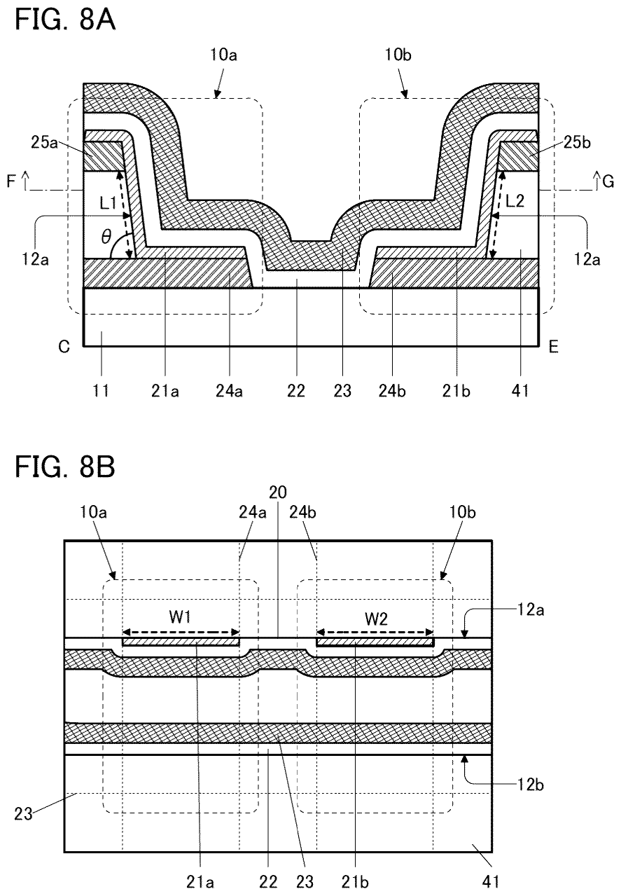

Next, the channel length, the channel width, and the like of the transistors are described with reference to FIG. 8A and FIG. 8B. FIG. 8A is a schematic cross-sectional view along the cutting line C-E in FIG. 1A.

A channel length L1 of the transistor 10a can be defined as, as illustrated in FIG. 8A, the length of a portion of the semiconductor layer 21a that is in contact with the insulating layer 41 on the shortest path connecting a portion in contact with the conductive layer 25a and a portion in contact with the conductive layer 24a. The same applies to a channel length L2 of the transistor 10b.

When the angle formed between the bottom surface of the insulating layer 41 and the side surface 12a in the slit 20, i.e., the angle (θ), is 90°, the channel lengths L1 and L2 are each equal to the height of the insulating layer 41. The channel lengths L1 and L2 can be larger than the thickness of the insulating layer 41 when the angle θ is smaller (or larger) than 90°. The angle θ is preferably smaller than 90° to improve step coverage in forming the semiconductor film to be the semiconductor layer 21a, the insulating layer 22, and the like. By contrast, when the angle θ is too small, the area occupied by the side surface 12a in the plan view is increased, which allows the transistor to occupy a larger area. Therefore, the angle between the bottom surface of the insulating layer 41 and the side surface 12a is preferably greater than or equal to 75° and less than or equal to 90°.

FIG. 8B is a cross-sectional view of the semiconductor device sectioned along the cutting line positioned at a height F-G in FIG. 8A. In FIG. 8B, the positions of the conductive layer 23, the conductive layer 24a, the conductive layer 24b, and the like are denoted by dashed lines.

The semiconductor layer 21a and the semiconductor layer 21b are provided along the side surface 12a of the insulating layer 41 in the slit 20. In the slit 20, the insulating layer 22 is provided on the inner side of the semiconductor layer 21a and the semiconductor layer 21b. The insulating layer 22 is provided in contact with the side surface 12a and the side surface 12b of the insulating layer 41. The conductive layer 23 is provided on the inner side of the insulating layer 22.

A channel width W1 of the transistor 10a can be rephrased as the length of a portion of the semiconductor layer 21a that is in contact with the side surface 12a in the direction along the slit 20. The same applies to a channel width W2 of the transistor 10b.

Since the semiconductor layer 21a, the semiconductor layer 21b, the insulating layer 22, and the like are formed along the inner wall of the slit 20 in the insulating layer 41, the thicknesses of the layers are sometimes reduced in the slit 20 by some film formation methods. For example, with a film formation method such as a sputtering method or a plasma CVD method, a film deposited on a surface inclined or perpendicular to a substrate surface tends to be thinner than a film deposited on a surface parallel to the substrate surface. By contrast, a film formation method such as an atomic layer deposition (ALD) method or a thermal CVD method allows a film with a uniform thickness to be formed on a surface with any angle. The semiconductor layer 21a, the semiconductor layer 21b, and the insulating layer 22 are preferably formed by an ALD method when the sidewall angle θ of the slit 20 in the insulating layer 41 is greater than or equal to 80° or greater than or equal to 85°, for example. In that case, the angle θ may be an angle greater than 90°.

### Transistor Arrangement Method

Next, an example of a method for arranging transistors will be described. In the description below, the case where one transistor is formed in one opening provided in an insulating layer is compared with the case of one embodiment of the present invention where two or more transistors share a side surface of a slit provided in an insulating layer.

Here, the three design rules are considered: the minimum width of one pattern (N), the minimum value of a distance between two patterns in the same layer (M), and the inclusion margin of two patterns in different layers (L).

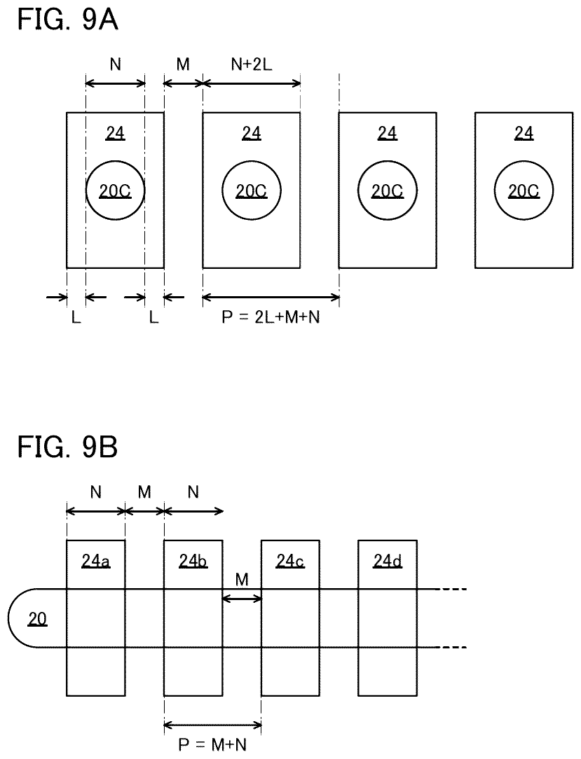

First, the case where one transistor is formed in one opening provided in an insulating layer is described. FIG. 9A illustrates a positional relationship between an opening 20C provided in the insulating layer and a conductive layer 24 in a plan view. In FIG. 9A, four conductive layers 24 are arranged with the minimum arrangement cycle P satisfying the design rule.

Since the opening 20C is positioned inward from the conductive layer 24, the minimum width of the conductive layer 24 is the sum of N, which is the minimum size of the opening 20C, and 2L, which are two inclusion margins which sandwich the opening 20C (N+2L). The minimum width between two adjacent conductive layers 24 is M. Thus, the arrangement cycle P of the conductive layers 24 is the sum of the width of the conductive layer 24 (N+2L) and the distance between the two conductive layers 24 (M) (P=2L+M+N).

Next, the case where two or more transistors are arranged on the side surface of the slit is described. FIG. 9B illustrates a positional relationship between the slit 20 provided in the insulating layer and the four conductive layers (the conductive layer 24a to a conductive layer 24d) that are provided to cross the slit in the plan view.

Note that here, an example in which the slit 20 includes an end portion is illustrated. This is an example of the case where the end portion of the slit 20 is arc-shaped.

Focusing on the slit 20 and the conductive layer 24a, the slit 20 is placed so as to cross the conductive layer 24a; hence, the inclusion margin in the lateral direction does not need to be taken into consideration. Therefore, the minimum width of the conductive layer 24a can be N, which is the minimum size. Furthermore, the distance between two adjacent conductive layers can be set to M, which is the minimum width. Thus, the arrangement cycle P of the conductive layers 24a and the like is the sum of the width (N) of the conductive layer 24a and the distance (M) between the two conductive layers (P=N+M).

In contrast to the case where one transistor is provided for one opening, the case where the same side surface of one slit is shared by a plurality of transistors does not substantially need to consider the inclusion margin as described above, and accordingly enables extremely dense arrangement of vertical transistors each occupying a small area.

More specifically, for example, in the case where a light exposure apparatus for a general display is assumed the minimum width N is 1.5 μm, the minimum value M of distance between patterns is 1 μm, and the inclusion margin L is 0.5 μm, the arrangement cycle P in FIG. 9A is 3.5 μm and the arrangement cycle in FIG. 9B is 2.5 μm. For example, in the case where a display device including pixels in each of which subpixels of three colors, red (R), green (G), and blue (B), are arranged in a stripe pattern is assumed, the minimum value of the arrangement cycle of the pixels is 10.5 μm in the example of FIG. 9A and the maximum value of the resolution is 2419 ppi. On the other hand, in the example of FIG. 9B, the minimum value of the pixel arrangement cycle is 7.5 μm, and the maximum value of the resolution is 3387 ppi. That is, a display with a resolution extremely higher than 3000 ppi can be manufactured over a glass substrate with a general manufacturing apparatus.

As described above, in the semiconductor device of one embodiment of the present invention, the transistors can be arranged extremely densely. Furthermore, when such a semiconductor device is used for a display device, a display device with extremely high resolution can be achieved. Note that the semiconductor device of one embodiment of the present invention is not limited to a display device, and can also be applied to a variety of devices using transistors (an arithmetic device, a memory device), and the like. In particular, since memory devices are required to be highly integrated, the semiconductor device of one embodiment of the present invention can be suitably used.

### Structure Example 2

An example of the case having a structure partly different from Structure example 1 above is described below. Note that the above description is referred to for the portions similar to those described above and the description thereof is omitted in some cases.

### Structure Example 2-1

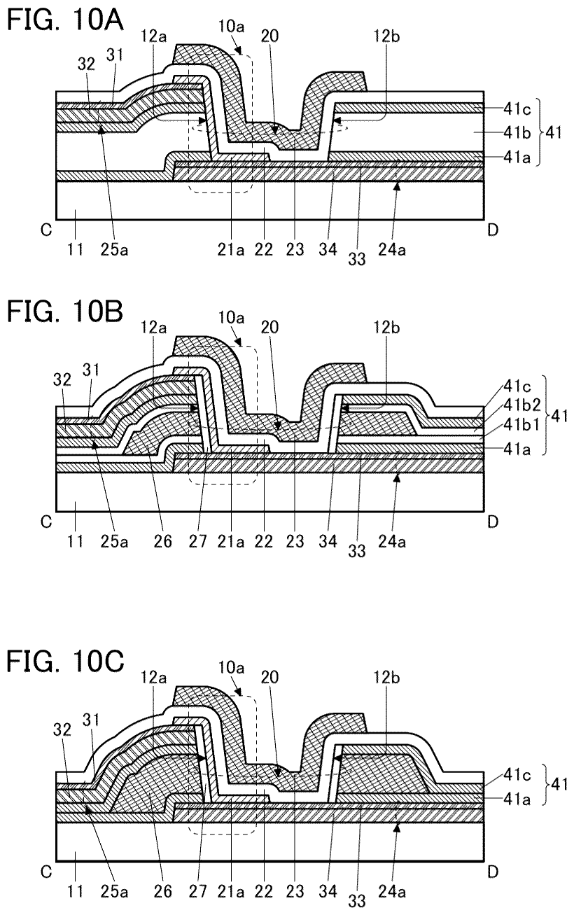

FIG. 10A is a schematic cross-sectional view of the transistor 10a. The structure illustrated in FIG. 10A is different from Structure example 1 mainly in that the insulating layer 41, the conductive layer 24a, and the conductive layer 25a each have a stacked-layer structure. Although not illustrated here, the transistor 10b can have a similar structure.

Note that although the transistor 10a is mainly described below, the same applies to the transistor 10b and the other transistors sharing the same side surface of the slit 20 with the transistor 10a. Furthermore, in the case where matters common to the components that are distinguished by alphabets, such as the conductive layer 24a and the conductive layer 24b, reference numerals without alphabets (e.g., the conductive layer 24) are sometimes used below.

The insulating layer 41 functions as an interlayer insulating layer (spacer) which insulates the conductive layer 24 from the conductive layer 25. Here, the case where a stacked-layer film of an insulating layer 41a, an insulating layer 41b, and an insulating layer 41c is used as the insulating layer 41 is illustrated.

The semiconductor layer 21 is provided in contact with the inner wall of the slit 20 in the insulating layer 41b. An oxide insulating film is preferably used as the insulating layer 41b. Specifically, an oxide insulating film from which oxygen is released by heating is preferably used. Accordingly, oxygen is supplied from the insulating layer 41b to the semiconductor layer 21 by heat applied during heat treatment or the manufacturing process, or the like, so that oxygen vacancies in the semiconductor layer 21 can be reduced. Moreover, a structure is preferable in which the insulating layer 41b is interposed between the insulating layer 41a and the insulating layer 41c having a barrier property against oxygen. This enables oxygen contained in the insulating layer 41b to be enclosed in a region surrounded by the insulating layer 41a, the insulating layer 41c, and the semiconductor layer 21. This can prevent oxygen in the insulating layer 41b to be released and reduced during the process; hence, oxygen can be supplied to the semiconductor layer 21 more efficiently.

A part of the semiconductor layer 21 that is in contact with the insulating layer 41b is a region where oxygen vacancies are reduced, i.e., an i-type region. The other part of the semiconductor layer 21 that is not in contact with the insulating layer 41b is preferably an n-type region including a large amount of carriers. That is, the part of the semiconductor layer 21 that is in contact with the insulating layer 41b can be referred to as a channel formation region and regions of the outer side of the channel formation region can be referred to as low-resistance regions (or a source region or a drain region).

The conductive layer 25 has a stacked-layer structure of a conductive layer 31 and a conductive layer 32. The conductive layer 31 is positioned over the conductive layer 32 and includes a portion in contact with the semiconductor layer 21. The conductive layer 24 has a stacked-layer structure of a conductive layer 33 and a conductive layer 34. The conductive layer 33 is positioned over the conductive layer 34 and includes a region in contact with the semiconductor layer 21.

The conductive layer 31 and the conductive layer 33 is in contact with the semiconductor layer 21. In the case where an oxide semiconductor is used for the semiconductor layer 21, a conductive material that is less likely to be oxidized, a conductive material that maintains low electric resistance even after being oxidized, or an oxide conductive material is preferably used for the conductive layer 31 and the conductive layer 33.

Meanwhile, the conductive layer 32 and the conductive layer 34 are preferably formed using a conductive material having higher conductivity than the material for the conductive layer 31 and the conductive layer 33. For example, a conductive material containing a metal, an alloy, a metal nitride film, or the like is preferably used.

### Structure Example 2-2

The structure illustrated in FIG. 10B is different from Structure example 1 mainly in including a conductive layer 26 and an insulating layer 27.

The conductive layer 26 functions as a second gate electrode (or a back gate electrode). The insulating layer 27 is positioned between the conductive layer 26 and the semiconductor layer 21 and functions as a second gate insulating layer (or a back gate insulating layer). A fixed potential or a given signal can be supplied to the conductive layer 26. By providing the conductive layer 26 and supplying an appropriate potential to the conductive layer 26, the threshold voltage of the transistor can be controlled. Furthermore, the potential of the back channel side of the semiconductor layer 21 can be fixed, so that variation in electrical characteristics can be reduced. The conductive layer 26 may be electrically connected to any one of the conductive layer 24, the conductive layer 25, and the conductive layer 23 and supplied with the same potential.

Here, an example in which the insulating layer 41 has a four-layer structure of the insulating layer 41a, an insulating layer 41b1, an insulating layer 41b2, and the insulating layer 41c is described. Hence, the conductive layer 26 is provided between the insulating layer 41b1 and the insulating layer 41b2.

The insulating layer 27 is provided along the side surfaces of the insulating layer 41a, the insulating layer 41b1, the conductive layer 26, the insulating layer 41b2, the insulating layer 41c, the conductive layer 32, and the conductive layer 31. For example, the insulating layer 27 can be formed in such a manner that a slit including the slit 20 is formed in the insulating layer 41a, the insulating layer 41b1, the conductive layer 26, the insulating layer 41b2, the insulating layer 41c, the conductive layer 32, and the conductive layer 31, an insulating film covering the slit is deposited by a deposition method achieving high coverage, and then anisotropic etching (e.g., dry etching) is performed. The insulating layer 27 is provided along the sidewall of the slit including the slit 20 and can also be referred to as a sidewall insulating film.

The conductive layer 26 may be provided to be shared by the transistor 10a and the transistor 10b or may be provided separately. When the conductive layer 26 is provided separately for each transistor, the threshold voltages of the transistors can be different from each other, and the circuit design flexibility can be increased.

The insulating layer 27 is provided in contact with the insulating layer 41bl and the insulating layer 41b2. Thus, the insulating layer 27 can be supplied with oxygen contained in the insulating layer 41b1 and the insulating layer 41b2 owing to heat applied during the process. Furthermore, the semiconductor layer 21a is supplied with oxygen from the insulating layer 27. Consequently, a highly reliable transistor can be achieved.

As illustrated in FIG. 10C, the insulating layer 41b1 and the insulating layer 41b2 are not necessarily provided. In this case, the conductive layer 26 is provided between the insulating layer 41a and the insulating layer 41c. In this case, an oxide insulating film from which oxygen is released by heating is preferably used as the insulating layer 27.

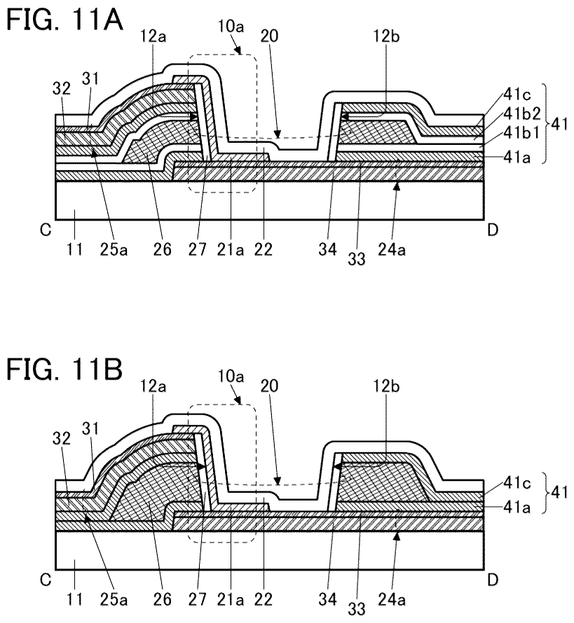

In the case where the conductive layer 26 and the insulating layer 27 are provided, a structure where the conductive layer 23 is not provided may be employed. FIG. 11A illustrates an example where the conductive layer 23 in FIG. 10B is not provided, and FIG. 11B illustrates an example in which the conductive layer 23 in FIG. 10C is not provided.

At this time, the conductive layer 26 functions as a gate electrode and is supplied with a signal or a potential related to the operation of the transistor 10a. The insulating layer 27 functions as a gate insulating layer.

It is preferable that the insulating layer 22 covering the semiconductor layer 21a be provided even when the conductive layer 23 is not provided. Here, the insulating layer 22 functions as a protective layer protecting the semiconductor layer 21a. In this case, an insulating film having a barrier property against oxygen and hydrogen is preferably used as the insulating layer 22. This can prevent not only diffusion of hydrogen from the outside into the semiconductor layer 21a but also diffusion of oxygen in the semiconductor layer 21a into the outside due to heat applied during the process or the like.

### Structure Example 2-3

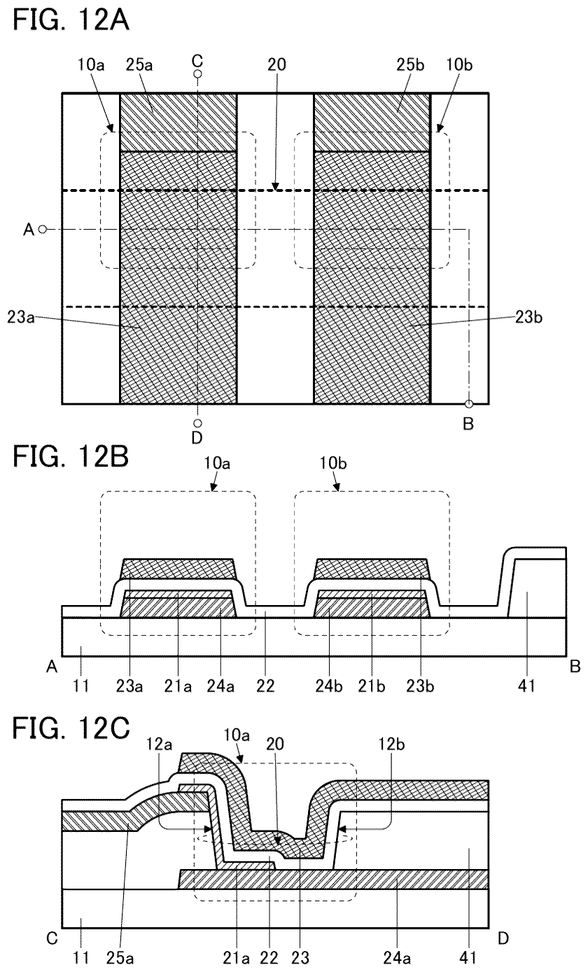

The structure illustrated in FIG. 12A to FIG. 12C is different from the above structure examples mainly in that conductive layers functioning as gate electrodes are provided separately in two transistors.

The transistor 10a includes a conductive layer 23a, and the transistor 10b includes a conductive layer 23b. The conductive layer 23a includes a portion overlapping with the semiconductor layer 21a with the insulating layer 22 therebetween, and the conductive layer 23b includes a portion overlapping with the semiconductor layer 21b with the insulating layer 22 therebetween. The conductive layer 23a and the conductive layer 23b can be supplied with different signals. Thus, the transistor 10a and the transistor 10b can operate at different timings.

The conductive layer 23a and the conductive layer 23b can be formed using the same conductive film. The conductive layer 23a and the conductive layer 23b are separated from each other by a region overlapping with the slit 20. That is, a region overlapping with neither the conductive layer 23a nor the conductive layer 23b is provided inside the slit 20.

### Structure Example 2-4

Here, a structure example of a semiconductor device that has a structure suitable for miniaturization by employing an LSI process is described below.

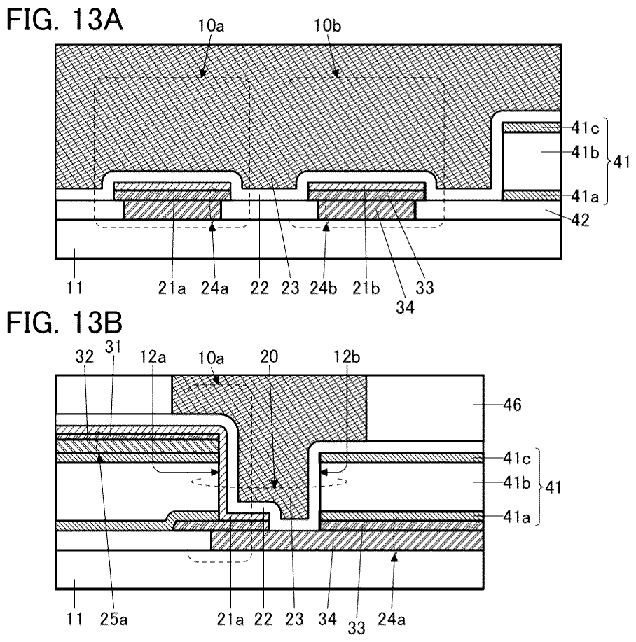

The structure illustrated in FIG. 13A and FIG. 13B is different from the above structure examples mainly in that end portions of the layers are processed substantially perpendicularly. The end portions of the layers are preferably processed substantially perpendicularly to reduce the area occupied by the transistors to facilitate miniaturization of the transistors.

The conductive layer 34 is embedded in an insulating layer 42. The conductive layer 33 is provided over the conductive layer 34 and the insulating layer 42. The insulating layer 41a is provided to cover the conductive layer 33 and the insulating layer 42. The insulating layer 41b is provided to cover the insulating layer 41a and has a planarized top surface. The insulating layer 41c is provided in contact with the planarized top surface of the insulating layer 41b.

Furthermore, the miniaturization reduces the width of the slit 20. Meanwhile, when the conductive layer 23 is too thin, wiring resistance increases; thus, the reduction in thickness is limited. Accordingly, as the miniaturization progresses, the conductive layer 23 is preferably made thick relative to the width of the slit 20. FIG. 13A and FIG. 13B illustrate an example in which an insulating layer 46 is provided over the insulating layer 41 with the insulating layer 22 therebetween and the conductive layer 23 is provided to fill the insulating layer 46 and the slit 20. In this case, it is preferable that the top surface of the insulating layer 46 and the top surface of the conductive layer 23 be planarized and substantially level with each other.

The insulating layer 41a, the insulating layer 41b, and the insulating layer 41c each have a side surface substantially perpendicular to the substrate. That is, the angle θ of the sidewall of the slit 20 in the insulating layer 41 is approximately 90°. Since the semiconductor layer 21, the insulating layer 22, and the conductive layer 23 are provided along the inner wall, which is substantially perpendicular to the substrate, of the slit 20 in the insulating layer 41, the semiconductor layer 21, the insulating layer 22, and the conductive layer 23 are preferably formed by a film formation method that provides high coverage, such as an ALD method or a thermal CVD method.

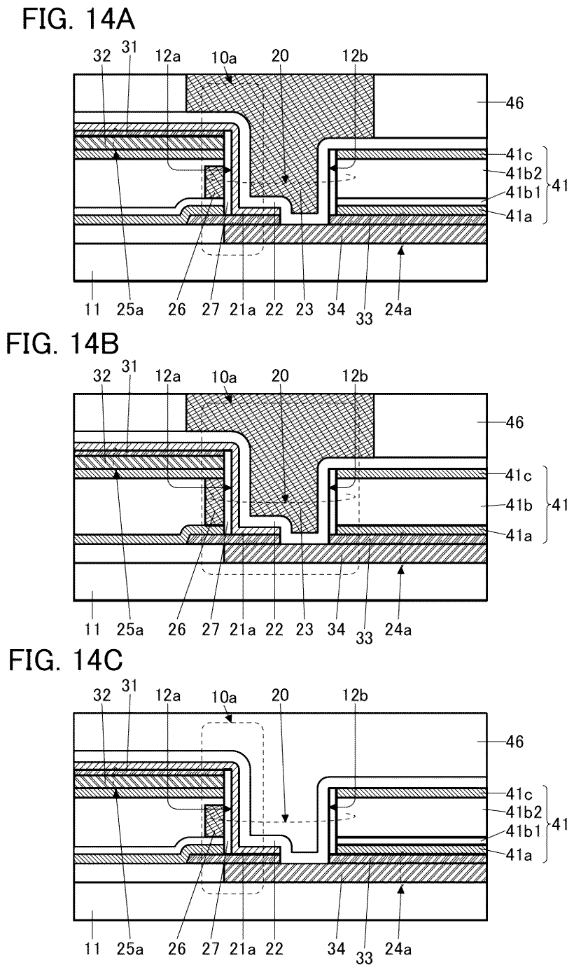

FIG. 14A and FIG. 14B illustrate an example in which the conductive layer 26 functioning as the second gate electrode and the insulating layer 27 functioning as the second gate insulating layer are included.

In FIG. 14A, the conductive layer 26 is provided between the insulating layer 41b1 and the insulating layer 41b2. The insulating layer 41b2 is provided to cover the conductive layer 26 and the insulating layer 41b1, and has a planarized top surface. The insulating layer 41c is provided to cover the planarized top surface of the insulating layer 41b2.

The insulating layer 27 is provided along the substantially perpendicular side surfaces of the insulating layer 41a, the insulating layer 41b1, the conductive layer 26, the insulating layer 41b2, the insulating layer 41c, the conductive layer 32, and the conductive layer 31.

FIG. 14B illustrates an example in which the conductive layer 26 is embedded in the insulating layer 41b. The bottom surface of the conductive layer 26 is in contact with the insulating layer 41a and the top surface of the conductive layer 26 is in contact with the insulating layer 41c. The top surfaces of the conductive layer 26 and the insulating layer 41b are planarized and substantially level with each other. The insulating layer 41c is provided to cover the planarized top surfaces of the conductive layer 26 and the insulating layer 41b.

FIG. 14C illustrates an example of the case where the conductive layer 23 in FIG. 14A is not provided. In this case, the conductive layer 26 functions as a gate electrode, and the insulating layer 27 functions as a gate insulating layer. The insulating layer 22 preferably functions as a protective layer. In this case, the insulating layer 46 is not necessarily provided.

Although not illustrated here, a structure where the conductive layer 23 in FIG. 14B is not provided may be employed.

The above is the description of the structure examples of the semiconductor device.

### Components

### <Substrate>

As a substrate where the transistor is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, gallium oxide, or gallium nitride. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Alternatively, a substrate including a nitride of a metal and a substrate including an oxide of a metal can be used. Other examples include an insulator substrate provided with a conductive layer or a semiconductor, a semiconductor substrate provided with a conductive layer or an insulating layer, and a conductor substrate provided with a semiconductor layer or an insulating layer. Alternatively, these substrates provided with elements may be used. Examples of the element provided for the substrate include a capacitor, a resistor, a switching element (including a transistor), a light-emitting element, a photoelectric conversion element, and a memory element.

### <Semiconductor Layer>

The semiconductor layer 21 preferably includes a metal oxide (an oxide semiconductor).

Examples of the metal oxide that can be used for the semiconductor layer 21 include In oxide, Ga oxide, and Zn oxide. The metal oxide preferably contains at least In or Zn. The metal oxide preferably contains two or three selected from In, an element M, and Zn. Note that the element M is a metal element or a metalloid element that has a high binding energy with oxygen, such as a metal element or a metalloid element whose binding energy with oxygen is higher than that of indium, for example. Specific examples of the element M include Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb. The element M included in the metal oxide is preferably one or more kinds of the above elements, and specifically, the element M is preferably one or more kinds selected from Al, Ga, Y, and Sn, and is further preferably Ga. Hereinafter, a metal oxide containing In, M, and Zn is referred to as In-M-Zn oxide in some cases.

When the metal oxide is an In-M-Zn oxide, the proportion of the number of In atoms is preferably higher than or equal to that of the number of M atoms in the In-M-Zn oxide. Examples of the atomic ratio of the metal elements of such In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5 or a composition in the neighborhood thereof. Note that a composition in the neighborhood includes the range of ±30% of an intended atomic ratio. By increasing the atomic proportion of indium in the metal oxide, the on-state current, field-effect mobility, or the like of the transistor can be increased.

The proportion of the number of In atoms may be less than that of the number of M atoms in the In-M-Zn oxide. Examples of the atomic ratio of the metal elements in such an In-M-Zn oxide include In:M:Zn=1:3:2, In:M:Zn=1:3:3, In:M:Zn=1:3:4 or a composition in the neighborhood thereof. By increasing the atomic ratio of M in the metal oxide, generation of oxygen vacancies can be inhibited.

For the semiconductor layer 21, for example, In oxide, In—Zn oxide, In—Ga oxide, In—Sn oxide, In—Ti oxide, In—Ga—Al oxide, In—Ga—Sn oxide, In—Ga—Zn oxide, In—Sn—Zn oxide, In—Al—Zn oxide, In—Ti—Zn oxide, In—Ga—Sn—Zn oxide, or In—Ga—Al—Zn oxide can be used. Alternatively, Ga—Zn oxide may be used. A material that does not contain Zn like indium oxide is preferred in that it improves the compatibility with an LSI manufacturing process. By contrast, a material that contains Zn is preferred in that crystallinity can be easily increased.

It is particularly preferable to use an In—Zn oxide in which the atomic ratio of metal elements is In:Zn=4:1 or In:Zn=2:1 or in the neighborhood thereof, or an In—Sn—Zn oxide in which the atomic ratio of metal elements is In:Sn:Zn=4:0.1:1 or In:Sn:Zn=2:0.1:1 or in the neighborhood thereof, in which case the field-effect mobility of the transistor can be favorably increased.

Note that the metal oxide may contain, instead of or in addition to indium, one or more kinds of metal elements belonging to a period of a higher number in the periodic table. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal elements include Y, Zr, Ag, Cd, Sn, Sb, Ba, Pb, Bi, La, Ce, Pr, Nd, Pm, Sm, and Eu. Note that La, Ce, Pr, Nd, Pm, Sm, and Eu are referred to as light rare earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

A sputtering method or an atomic layer deposition (ALD) method can be suitably used to form the metal oxide. In particular, a film of the metal oxide is preferably formed by an ALD method, which enables good coverage. Note that in the case where the metal oxide is formed by a sputtering method, the composition of the deposited metal oxide may be different from the composition of a target. In particular, the content of the zinc in the deposited metal oxide may be reduced to approximately 50% of that of the target.

In this specification and the like, the content of a certain metal element in the metal oxide refers to the ratio of the number of atoms of the element to the total number of atoms of metal elements contained in the metal oxide. In the case where a metal oxide contains a metal element X, a metal element Y, and a metal element Z whose atomic numbers are respectively represented by A_{X}, A_{Y}, and A_{Z}, the content of the metal element X can be represented by A_{X}/(A_{X}+A_{Y}+A_{Z}). Moreover, in the case where the atomic ratio of the metal element X, the metal element Y, and the metal element Z contained in the metal oxide is represented by B_{X}; B_{Y}; B_{Z}, the content ratio of the metal element X can be represented by B_{X}/(B_{X}+B_{Y}+B_{Z}).

For example, in the case of the metal oxide containing In, higher content of In enables the transistor to have high on-state current.

With use of a metal oxide that does not contain Ga or has low Ga content in the semiconductor layer 21, the transistor can be highly reliable against positive bias application. That is, the amount of change in the threshold voltage of the transistor in the PBTS (positive bias temperature stress) test can be small. Meanwhile, with use of a metal oxide that contains Ga, the Ga content is preferably lower than the In content. Thus, the transistor with high mobility and high reliability can be achieved.

Meanwhile, the high content of Ga enables the transistor to be highly reliable against light. That is, the amount of change in the threshold voltage of the transistor in the NBTIS (negative bias temperature illumination stress) test can be small. Specifically, in a metal oxide in which the atomic ratio of Ga is higher than or equal to that of In, the band gap is increased and accordingly the amount of change in the threshold voltage of the transistor in the NBTIS test can be reduced.

Furthermore, a metal oxide having a high Zn content has high crystallinity whereby diffusion of impurities can be inhibited. Consequently, a change in electrical characteristics of the transistor can be inhibited, and the reliability of the transistor can be increased.

The semiconductor layer 21 may have a stacked-layer structure of two or more metal oxide layers. The two or more metal oxide layers included in the semiconductor layer 21 may have the same composition or substantially the same compositions. Employing a stacked-layer structure of metal oxide layers having the same composition can reduce the manufacturing cost because the metal oxide layers can be formed using the same sputtering target. Note that a stacked-layer structure including two or more oxide semiconductor layers having different compositions may be employed. The use of an ALD method can form a metal oxide layer with a composition that continuously changes in the thickness direction. This not only increases the range of choices for design without need for use of a film with a predetermined composition but also prevents generation of an interface state or the like between two layers with different compositions; thus, the electrical characteristics and reliability can be improved.

In the case where the semiconductor layer 21 has a two-layer structure, the second layer, i.e., the layer closer to the gate electrode, preferably includes a material with higher mobility (higher conductivity) than the first layer. This structure enables the transistor to have normally-off characteristics and a high on-state current. Consequently, both low power consumption and high performance can be achieved. Alternatively, the first layer, i.e., the layer in contact with the source electrode and the drain electrode, may include a material having higher mobility than the second layer. In that case, contact resistance between the semiconductor layer 21 and the source electrode or the drain electrode can be reduced and the parasitic resistance can be reduced accordingly, so that the transistor can have a high on-state current.

In the case where the semiconductor layer 21 has a three-layer structure, the second layer preferably includes a material having higher mobility than the first layer and the third layer. Accordingly, a transistor having a high on-state current and high reliability can be obtained.

It is preferable to use a metal oxide layer having crystallinity as the semiconductor layer 21. For example, a metal oxide layer having a CAAC (c-axis aligned crystal) structure, a polycrystalline structure, a nano-crystal (nc) structure, or the like can be used. With the use of the metal oxide layer having crystallinity as the semiconductor layer 21, the density of defect states in the semiconductor layer 21 can be reduced, which enables the semiconductor device to have high reliability.

The higher the crystallinity of the metal oxide layer used as the semiconductor layer 21 is, the lower the density of defect states in the semiconductor layer 21 can be. By contrast, the use of a metal oxide layer having low crystallinity achieves a transistor through which a large amount of current can flow.

A transistor including an oxide semiconductor (hereinafter referred to as an OS transistor) has much higher field-effect mobility than a transistor including amorphous silicon. In addition, the OS transistor has an extremely low leakage current between a source and a drain in an off state (hereinafter also referred to as off-state current), and charge accumulated in a capacitance that is connected in series with the transistor can be held for a long period. Furthermore, the power consumption of the semiconductor device can be reduced with the OS transistor.

The semiconductor device of one embodiment of the present invention can be used for a display device, for example. To increase the emission luminance of a light-emitting device included in a pixel circuit in the display device, it is necessary to increase the amount of current flowing through the light-emitting device. To increase the current amount, the source-drain voltage of a drive transistor included in the pixel circuit needs to be increased. Since the OS transistor has a higher breakdown voltage between a source and a drain than a transistor using silicon (hereinafter, referred to as a Si transistor), a high voltage can be applied between the source and the drain of the OS transistor. Accordingly, when an OS transistor is used as the drive transistor included in the pixel circuit, the amount of current flowing through the light-emitting device can be increased, so that the emission luminance of the light-emitting device can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing through the light-emitting device can be precisely controlled. Consequently, the number of gray levels in the pixel circuit can be increased. Moreover, current can be made flow stably even when the electrical characteristics (e.g., resistance) in the light-emitting device change or the electrical characteristics in the light-emitting device vary.

As described above, by using an OS transistor as the driving transistor included in the pixel circuit, it is possible to achieve “inhibition of black floating”, “increase in emission luminance”, “increase in the number of gray levels”, “inhibition of influence of a manufacturing variation in light-emitting devices”, and the like.

A change in electrical characteristics of an OS transistor due to radiation irradiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Note that the semiconductor material that can be used for the semiconductor layer 21 is not limited to the oxide semiconductor. For example, a single-element semiconductor or a compound semiconductor can be used. Examples of the single-element semiconductor include silicon (such as single crystal silicon, polycrystalline silicon, microcrystalline silicon, and amorphous silicon) and germanium. Examples of the compound semiconductor include gallium arsenide and silicon germanium. Examples of the compound semiconductor include an organic semiconductor, a nitride semiconductor, and an oxide semiconductor. These semiconductor materials may include an impurity as a dopant.

Alternatively, the semiconductor layer 21 may contain a layered substance that functions as a semiconductor. The layered substance is a general term of a group of materials having a layered crystal structure. The layered crystal structure is a structure in which layers formed by covalent bonding or ionic bonding are stacked with bonding such as the Van der Waals bonding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substances include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

There is no particular limitation on the crystallinity of a semiconductor material used for the semiconductor layer 21, and any of an amorphous semiconductor, a single crystal semiconductor, and a semiconductor having crystallinity other than single crystal (a polycrystalline semiconductor, a microcrystalline semiconductor, or a semiconductor partly including crystal regions) may be used. A semiconductor having crystallinity is preferably used, in which case degradation of the transistor characteristics can be inhibited.

### <Gate Insulating Layer>

The insulating layer 22 (and the insulating layer 27) functions as the gate insulating layer of the transistor. In the case where the semiconductor layer 21 is formed using an oxide semiconductor, an oxide insulating film is preferably used as at least a film of the insulating layer 22 that is in contact with the semiconductor layer 21. For example, one or more of silicon oxide, silicon oxynitride, aluminum oxide, aluminum oxynitride, hafnium oxide, hafnium oxynitride, gallium oxide, gallium oxynitride, yttrium oxide, yttrium oxynitride, and Ga—Zn oxide can be used. In addition, as the insulating layer 22, a nitride insulating film of silicon nitride, silicon nitride oxide, aluminum nitride, or aluminum nitride oxide can also be used. The insulating layer 22 may also have a stacked-layer structure, e.g., a stacked-layer structure including at least one oxide insulating film and at least one nitride insulating film.

Note that in this specification and the like, an oxynitride refers to a material that contains more oxygen than nitrogen. A nitride oxide refers to a material that contains more nitrogen than oxygen.

It is preferable for the insulating layer 22 to include stacked insulating materials formed of any of the high-k materials, and it is preferable to use a stacked-layer structure of a high relative permittivity (high-k) material and a material having a higher dielectric strength than the high-k material. For the insulating layer 22, an insulating film in which zirconium oxide, aluminum oxide, and zirconium oxide are stacked in this order (also referred to as ZAZ) can be used, for example. Alternatively, an insulating film in which zirconium oxide, aluminum oxide, zirconium oxide, and aluminum oxide are stacked in this order (also referred to as ZAZA) can be used, for example. Alternatively, an insulating film in which hafnium zirconium oxide, aluminum oxide, hafnium zirconium oxide, and aluminum oxide are stacked in this order can be used, for example. The use of stacked insulators with relatively high dielectric strength, such as aluminum oxide, can increase the dielectric strength and inhibit electrostatic breakdown of the capacitor.

Alternatively, a material that exhibits ferroelectricity may be used for the insulating layer 22. Examples of the material that exhibits ferroelectricity include metal oxides such as hafnium oxide, zirconium oxide, and HfZrO_{X} (X is a real number greater than 0).

### <Conductive Layer>

Each of the conductive layer 24 and the conductive layer 25 is in contact with the semiconductor layer 21. Here, when an oxide semiconductor is used for the semiconductor layer 21, a portion of the conductive layer 24 or the conductive layer 25 which is in contact with the semiconductor layer 21 is formed using, for example, a metal that is likely to be oxidized, such as aluminum, an insulating oxide (e.g., aluminum oxide) is formed between the conductive layer 24 or the conductive layer 25 and the semiconductor layer 21, which might prevent conduction between the conductive layer 24 or the conductive layer 25 and the semiconductor layer 21. Therefore, a conductive material that is less likely to be oxidized, a conductive metal oxide material that maintains low electric resistance even after being oxidized, or an oxide conductive material is preferably used for at least the portions of the conductive layer 24 and the conductive layer 25 which are in contact with the semiconductor layer 21.

For example, it is preferable to use titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, an oxide containing lanthanum and nickel, or the like as the conductive layer 24 and the conductive layer 25. These materials are preferable because they are conductive materials that are less likely to be oxidized or materials that maintain the conductivity even when oxidized.

Alternatively, a conductive metal oxide such as indium oxide, zinc oxide, In—Sn oxide, In—Zn oxide, In—W oxide, In—W—Zn oxide, In—Ti oxide, In—Ti—Sn oxide, In—Sn—Si oxide, Ga—Zn oxide, or the like can be used. A conductive metal oxide containing indium is particularly preferable because of its high conductivity. Alternatively, the above-described oxide material such as In—Ga—Zn oxide that can be used for the semiconductor layer 21 can be used for the conductive layer when the carrier concentration is increased.

Examples of the structures of the conductive layer 24 and the conductive layer 25 include a single-layer structure of the above conductive metal oxide film, a three-layer structure in which a titanium nitride film, a tungsten film, and a titanium nitride are stacked in this order, a two-layer structure in which a ruthenium film or a ruthenium oxide film is stacked over tungsten, a two-layer structure in which a ruthenium film or a ruthenium oxide film is stacked over the above conductive metal oxide film, a two-layer structure in which the above conductive metal oxide film is stacked over a ruthenium film or a ruthenium oxide film. Note that ruthenium is a material that is not easily etched and thus is preferably as thin as possible when used; ruthenium used preferably has a thickness greater than or equal to 0.1 nm and less than or equal to 2 nm, for example.

The conductive layer 23 (and the conductive layer 26) functions as a gate electrode and a variety of conductive materials can be used. For the conductive layer 23, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum, for example; an alloy containing any of the above metal elements as its component; or the like. It is also possible to use a nitride or an oxide of any of the above metals or the alloy. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

For the conductive layer 23, the nitride and the oxide that can be used for the conductive layer 24 and the conductive layer 25 may be used.

The conductive layer 23, the conductive layer 24, and the conductive layer 25 also serve as wirings and thus are preferably formed using stacked low-resistance conductive materials. For example, a conductive material that can be used for the above-described conductive layer 23 can also be used for the lower layers in the conductive layer 24 and the conductive layer 25.

### <Insulating Layer>

The insulating layer 41b can be used as an interlayer insulating film. For example, the insulating layer 41b is preferably formed by a film formation method such as a sputtering method or a plasma CVD method. It is particularly preferable to employ a sputtering method, in which a hydrogen gas does not need to be used as a film formation gas, to form a film having an extremely low hydrogen content. Consequently, supply of hydrogen to the semiconductor layer 21 is inhibited and the electrical characteristics of the transistor 10a and transistor 10b can be stabilized.

The insulating layer 41b is in contact with the channel formation region of the semiconductor layer 21 and thus is preferably formed using an oxide insulating film. Specifically, an oxide insulating film from which oxygen is released by heating is preferably used. An oxide insulating film that can be used as the above-described gate insulating layer can be used as the insulating layer 41b.

Since the insulating layer 41b serves as an interlayer insulating layer, it is preferably formed by a film formation method that enables a higher film formation rate than those of the other insulating layers. For example, a film of TEOS (Tetra-Ethyl-Ortho-Silicate, chemical formula: Si(OC₂H₅)₄) formed by a plasma CVD method can also be used for the insulating layer 41. Thus, the productivity can be improved.

As each of the insulating layer 41a and the insulating layer 41c, a film through which hydrogen hardly diffuses is preferably used. The insulating layer 41a and the insulating layer 41c which do not easily allow diffusion of hydrogen are provided above and below the insulating layer 41b, respectively, thereby preventing entry of hydrogen from the outside into the insulating layer 41b in contact with the semiconductor layer 21.

As the insulating layer 41a and the insulating layer 41c, for example, one or more of silicon nitride, silicon nitride oxide, silicon oxynitride, aluminum oxide, aluminum oxynitride, aluminum nitride, hafnium oxide, and hafnium aluminate can be used. Silicon nitride and silicon nitride oxide can be particularly suitably used for the insulating layer 41a and the insulating layer 41c because the silicon nitride and the silicon nitride oxide release fewer impurities (e.g., water and hydrogen) and are less likely to transmit oxygen and hydrogen (have a barrier property).

Moreover, silicon nitride, silicon nitride oxide, aluminum oxide, aluminum oxynitride, aluminum nitride, hafnium aluminate, and the like have a barrier property against oxygen and hydrogen and thus can be suitably used for the insulating layer 41a and the insulating layer 41c.

The insulating layer 42 functions as an interlayer insulating layer. For the insulating layer 42, an insulating material that can be used for the insulating layer 41b or an insulating material that can be used for the insulating layer 41a and the insulating layer 41c can be used as appropriate.

The above is the description of the components.

### Structure Example of Display Device

Next, a structure example of a display device using the semiconductor device of one embodiment of the present invention is described.

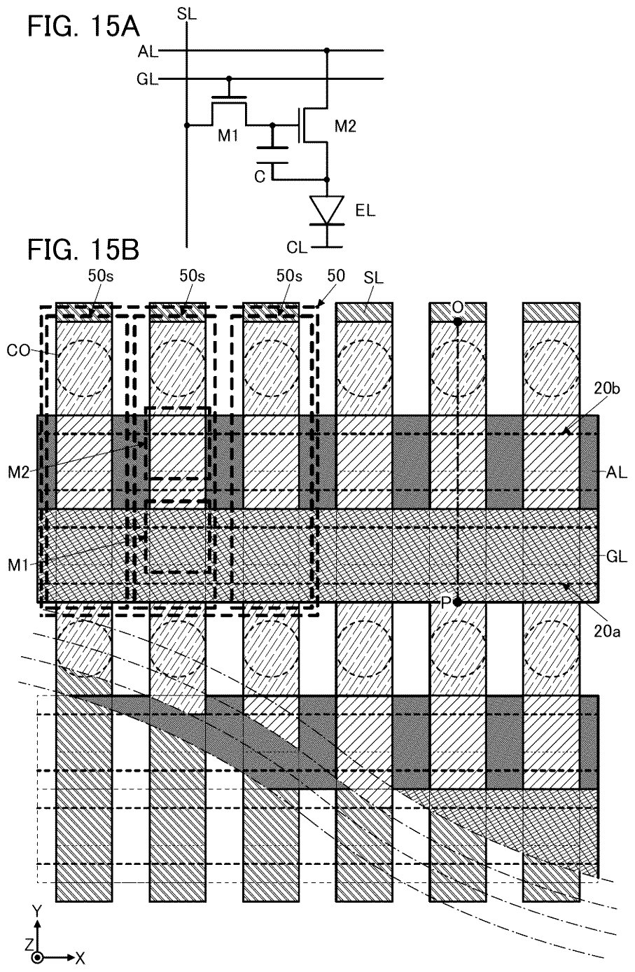

FIG. 15A is a circuit diagram of a pixel of a display device described below as an example. The pixel includes a transistor M1, a transistor M2, a capacitor C, and a light-emitting element EL. A wiring SL, a wiring GL, a wiring AL, and a wiring CL are electrically connected to the pixel. The wiring SL functions as a source line (signal line), the wiring GL functions as a gate line (scan line), and the wiring AL and the wiring CL function as power supply lines. A potential higher than that of the wiring CL is supplied to the wiring AL.

A gate of the transistor MI is electrically connected to the wiring GL, one of a source and a drain of the transistor MI is electrically connected to the wiring SL, and the other thereof is electrically connected to a gate of the transistor M2 and one electrode of the capacitor C. One of a source and a drain of the transistor M2 is electrically connected to the wiring AL, and the other thereof is electrically connected to the other electrode of the capacitor C and one electrode of the light-emitting element EL. The other electrode of the light-emitting element EL is electrically connected to the wiring CL.

The transistor of one embodiment of the present invention can be used as the transistor M1 and the transistor M2. Specifically, two transistors MI provided in two adjacent subpixels share one slit, and two transistors M2 share another slit. Accordingly, the distance between adjacent subpixels can be reduced, so that a high-resolution display device can be achieved.

Although the pixel including two transistors and one capacitor is illustrated here, one embodiment of the present invention is not limited thereto. For example, the number of transistors may be one, or three or more. Furthermore, the capacitor is not necessarily provided or two or more capacitors may be provided.

### Structure Example 1

FIG. 15B illustrates an example of a layout of a backplane of a pixel. FIG. 15B is a schematic top view of 2×2 pixels 50. In FIG. 15B, the X direction, the Y direction, and the Z direction that are orthogonal to each other are indicated by arrows.

The pixel 50 includes three subpixels 50s aligned in the X direction. The subpixels 50s each include the transistor MI, the transistor M2, and a connection portion CO. The connection portion CO is a portion where a contact hole for connection to the pixel electrode (not illustrated) of the light-emitting element EL is provided. For example, three subpixels included in one pixel 50 are provided with light-emitting elements corresponding to red (R), green (G), and blue (B).

Note that the number of subpixels 50s included in one pixel 50 is not limited to three, and the pixel 50 may include two or four or more subpixels.

The wiring AL and the wiring GL extend in the X direction, and the wiring SL extends in the Y direction. The transistor M1, the transistor M2, and the connection portion CO are arranged in the Y direction. The slit 20a and the slit 20b are provided to extend in the X direction.

The plurality of transistors MI aligned in the X direction are each placed along one side surface of the slit 20a. The plurality of transistors M2 aligned in the X direction are each placed along one side surface of the slit 20b.

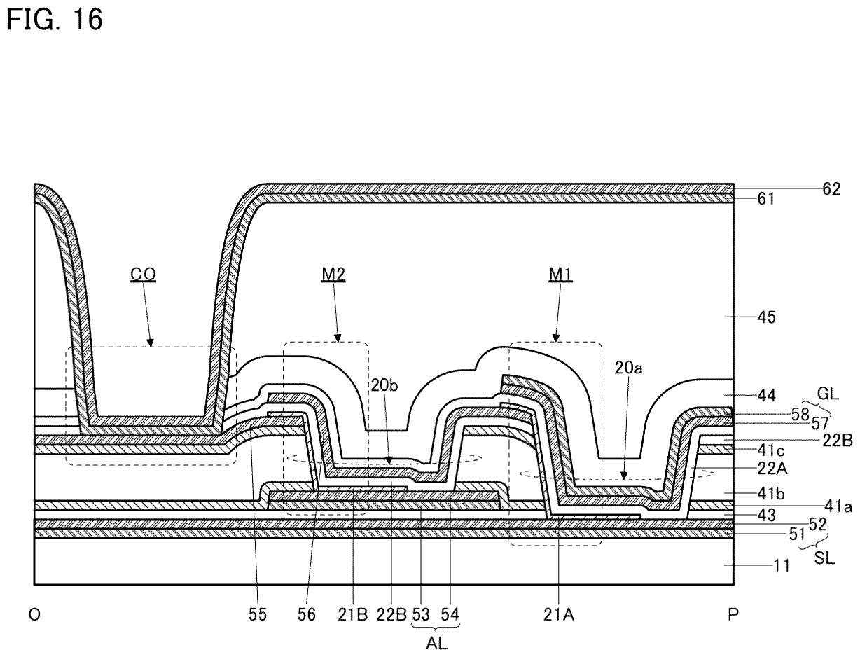

Next, a cross-sectional structure example of the display device is described. FIG. 16 is a schematic cross-sectional view along the dashed-dotted line O-P in FIG. 15B. FIG. 16 illustrates a cross section including the connection portion CO, the transistor M2, and the transistor M1.

The transistor M1 includes a semiconductor layer 21A, an insulating layer 22A functioning as a gate insulating layer, a conductive layer 57 and a conductive layer 58 functioning as a gate electrode, a conductive layer 51 and a conductive layer 52 functioning as one of a source electrode and a drain electrode, and a conductive layer 56 functioning as the other of the source electrode and the drain electrode.

The transistor M2 includes a semiconductor layer 21B, an insulating layer 22B functioning as a gate insulating layer, the conductive layer 56 functioning as a gate electrode, a conductive layer 53 and a conductive layer 54 functioning as one of a source electrode and a drain electrode, and a conductive layer 55 functioning as the other thereof.

The transistors exemplified in Structure example 1 or Structure example 2 above can be used as the transistor M1 and the transistor M2.

The connection portion CO includes a portion where part of the conductive layer 55 is in contact with a conductive layer 61 and a conductive layer 62. The conductive layer 61 functions as a pixel electrode of a light-emitting element. A conductive layer 62 functions as an optical adjustment layer. In the case of a high-resolution display device, wirings constituting a circuit of a backplane and the like are integrated densely; thus, the light-emitting element preferably has a top-emission structure in order to increase the aperture ratio. Thus, for the conductive layer 61, a conductive material having high visible light reflectance is preferably used. For the conductive layer 62, a conductive material having a transmitting property with respect to visible light can be used. The transistor M2 is connected to a pixel electrode of the light-emitting element through the connection portion CO.

A stack of the conductive layer 51 and the conductive layer 52 is provided over the insulating layer 11 as the wiring SL. The above descriptions of the conductive layer 32 and the conductive layer 31 can be referred to for the conductive layer 51 and the conductive layer 52, respectively. A conductive material with low resistance and an oxide conductor material are preferably used for the conductive layer 51 and the conductive layer 52, respectively. The wiring SL includes a portion overlapping with the transistor M2 and the connection portion CO.

An insulating layer 43 functioning as an interlayer insulating layer is provided over the wiring SL, and a stack of the conductive layer 53 and the conductive layer 54 is provided over the insulating layer 43 as the wiring AL. The above descriptions of the conductive layer 32 and the conductive layer 31 can be referred to for the conductive layer 53 and the conductive layer 54, respectively. A conductive material with low resistance and an oxide conductor material are preferably used for the conductive layer 53 and the conductive layer 54, respectively.

The insulating layer 41a, the insulating layer 41b, and the insulating layer 41c are provided over the insulating layer 43 and the wiring AL, and the conductive layer 55 is provided over the insulating layer 41c. An oxide conductor material is preferably used for the conductive layer 55. The slit 20b reaching the conductive layer 54 is provided in the insulating layer 41c, the insulating layer 41b, and the insulating layer 41a. The conductive layer 55 is positioned only on the connection portion CO side of the slit 20b, not on the opposite side. The top surface shapes of the side surface of the conductive layer 55 on the transistor M2 side and the side surface of the slit 20b are substantially the same. The semiconductor layer 21B is provided in contact with the conductive layer 55, the conductive layer 54, and the side surfaces of the insulating layer 41a, the insulating layer 41b, and the insulating layer 41c in the slit 20b. The insulating layer 22B is provided so as to cover the semiconductor layer 21B, and the conductive layer 56 is provided over the insulating layer 22B.

The slit 20a reaching the conductive layer 52 is provided in the insulating layer 41c, the insulating layer 41b, the insulating layer 41a, and the insulating layer 43, and a slit whose top surface shape is substantially the same as that of the slit 20a is provided also in the insulating layer 22B and the conductive layer 56. The semiconductor layer 21A is in contact with the top surface of the conductive layer 56, the top surface of the conductive layer 52, a side surface of the insulating layer 22B, and side surfaces of the insulating layer 41a, the insulating layer 41b, the insulating layer 41c, and the insulating layer 43 in the slit 20a. An insulating layer 22A is provided to cover the semiconductor layer 21A, and the conductive layer 57 and the conductive layer 58 are stacked over the insulating layer 22A. A conductive material having lower resistance than the conductive layer 57 is preferably used for the conductive layer 58. For example, a titanium film and a copper film can be used for the conductive layer 57 and the conductive layer 58, respectively.

An insulating layer 44 is provided to cover the conductive layer 58 and the insulating layer 22A and can function as a protective film so as to prevent diffusion of impurities such as water from the outside. For the insulating layer 44, a single layer or stacked layers of inorganic insulating films can be used. Furthermore, an insulating layer 45 is provided to cover the insulating layer 44. The insulating layer 45 functions as a planarization layer. An organic insulating material can be used for the insulating layer 45.

The conductive layer 61 and the conductive layer 62 are stacked over the insulating layer 45. In the connection portion CO, an opening reaching the conductive layer 55 is provided in the insulating layer 45, the insulating layer 44, the insulating layer 22A, and the insulating layer 22B. The conductive layer 61 and the conductive layer 55 are electrically connected to each other through the opening.

In the structure exemplified here, all of the semiconductor layer, the gate insulating layer, the source electrode, and the drain electrode of the transistor MI are formed using layers different from those of the transistor M2. The upper electrode (the conductive layer 56) of the transistor M1 also serves as the gate electrode of the transistor M2. When different transistors are separately formed using different layers in this manner, a pixel circuit occupying a small area can be formed.

As described above, with the use of the transistors of one embodiment of the present invention, pixels including display elements (here, light-emitting elements) can be arranged with extremely high density; accordingly, a high-resolution display device that has been difficult to achieve can be achieved. With the pixel exemplified in FIG. 15B and the like, a display device with a resolution over 3000 ppi (e.g., 3387 ppi) can be achieved when the wiring SL has a line width of 1.5 μm, the distance between the wirings SL is 1 μm, and the inclusion margin between the wiring and each of the slit 20a and the slit 20b is 0.5 μm, for example. Here, since the pixel includes at least one transistor and at least one display element, it can also be said that the display elements are arranged with a density higher than or equal to 3000 ppi in the display device.

As illustrated in FIG. 16, in the slit 20b, a portion where the semiconductor layer 21B is not provided includes a region where the insulating layer 22B and the insulating layer 41b are in contact with each other. Also in the slit 20a, a portion where the semiconductor layer 21A is not provided includes a region where the insulating layer 22A and the insulating layer 41b are in contact with each other. At this time, in the case where the insulating layer 22A and the insulating layer 22B easily diffuse oxygen, oxygen in the insulating layer 41b is diffused through the insulating layer 22A or the insulating layer 22B by heat during the manufacturing process or the like and the amount of oxygen that can be supplied to the semiconductor layer 21A and the semiconductor layer 21B might be reduced. Thus, for the insulating layer 22B and the insulating layer 22A, a film having a barrier property against oxygen is preferably used. For example, each of the insulating layer 22B and the insulating layer 22A preferably has a stacked-layer structure in which an oxide film with high affinity with the oxide semiconductor is provided on the side in contact with the semiconductor layer 21A or the semiconductor layer 21B and an inorganic insulating film having a barrier property against oxygen is stacked thereover.

Examples of the inorganic insulating film having a barrier property against oxygen include silicon nitride, silicon nitride oxide, aluminum oxide, aluminum oxynitride, aluminum nitride oxide, aluminum nitride, hafnium oxide, an oxide containing hafnium and silicon (hafnium silicate), an oxide containing hafnium and aluminum (hafnium aluminate), gallium oxide, and an oxide containing gallium and zinc.

Nitriding a surface of the insulating layer 41b which is not covered with the semiconductor layers so as to reduce the infusibility of oxygen can be given as an example of a method for inhibiting diffusion of oxygen in the insulating layer 41b in a portion where the transistor M2 is not provided in the slit 20b and a portion where the transistor MI is not provided in the slit 20a. Examples of the treatment for nitriding the surface of the insulating layer 41b include plasma treatment in an atmosphere containing nitrogen such as nitrogen (N₂) or dinitrogen monoxide (N₂O). For example, the plasma treatment is performed before the formation of the insulating layer 22A or the insulating layer 22B, whereby the exposed side surface of the insulating layer 41b can be favorably nitrided.

Although not illustrated here, there is a portion where the insulating layer 22A and the wiring GL (the conductive layer 57 and the conductive layer 58) are provided to cover an end portion of the wiring SL (the conductive layer 51 and the conductive layer 52) in the slit 20a. At this time, in the case where the step coverage with the insulating layer 22A is low, the thickness of the insulating layer 22A is reduced at the end portion of the wiring SL, which might decrease the breakdown voltage. This might cause defects such as an increase in leakage current between the wiring SL and the wiring GL and dielectric breakdown of the insulating layer 22A. Therefore, to improve step coverage with the insulating layer 22A, the conductive layer 51 and the conductive layer 52 are preferably processed to have an end portion with a tapered shape. The insulating layer 22A is preferably formed by a deposition method with high step coverage, such as a CVD method or a PVD method such as an ALD method. Since there is also a portion where an end portion of the wiring AL (the conductive layer 53 and the conductive layer 54) is positioned in the slit 20b, it is preferable to form end portions of the conductive layer 53 and the conductive layer 54 into a tapered shape and to employ a deposition method that enables favorable coverage also for the insulating layer 22B.

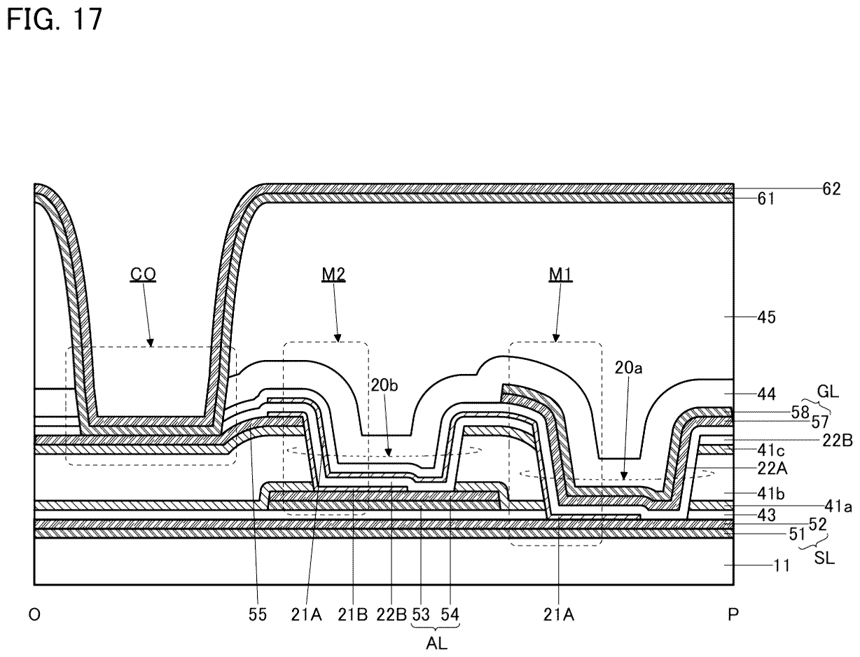

FIG. 17 illustrates a schematic cross-sectional view of a display device having a structure partly different from the above. The structure illustrated in FIG. 17 is different from the above structure examples mainly in not including the conductive layer 56.

The semiconductor layer 21A of the transistor MI extends to the slit 20b and includes a portion overlapping with the semiconductor layer 21B with the insulating layer 22B therebetween in the slit 20b. That is, part of the semiconductor layer 21 A functions as the gate electrode of the transistor M2. In other words, the semiconductor layer 21A also serves as the semiconductor layer of the transistor MI and the gate electrode of the transistor M2. This structure is preferable because the manufacturing process can be simplified.

In the structure illustrated in FIG. 17, the resistance of a portion of the semiconductor layer 21A that is not covered with the wiring GL is preferably reduced. For example, the resistance of the semiconductor layer 21A can be reduced when an impurity which generates carriers is supplied to the semiconductor layer 21A through the insulating layer 22A using the wiring GL as a mask. Examples of the impurity include hydrogen, nitrogen, noble gases, metal elements, and nonmetallic elements. Note that a portion of the semiconductor layer 21A that is not in contact with the insulating layer 41b might include a large amount of carriers because oxygen supply is insufficient. Thus, in the case where the portion of the semiconductor layer 21A that is not covered with the wiring GL has sufficiently low resistance, such treatment is not necessarily performed.

### Structure Example 2

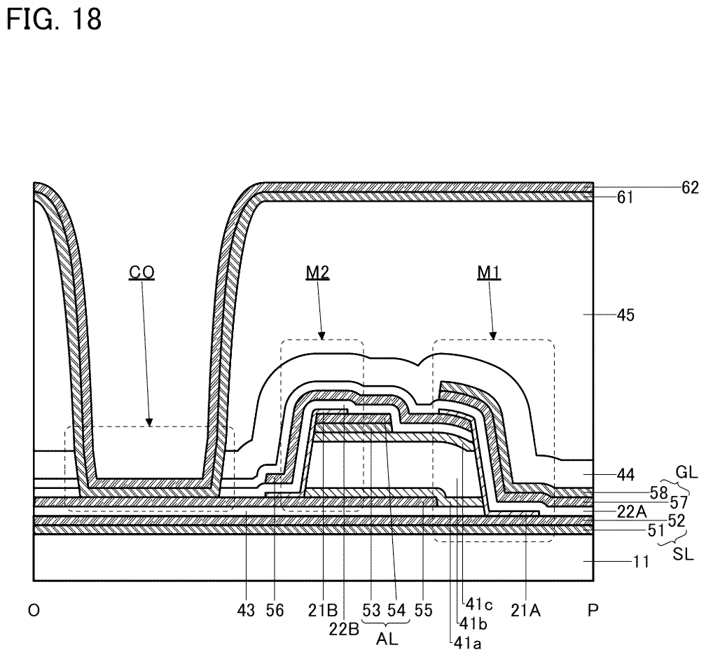

FIG. 18 is a schematic cross-sectional view of a display device described below as an example. A structure illustrated in FIG. 18 is different from that in Structure example 1 mainly in the shape of the insulating layer 41.

The insulating layer 41 is processed into an isolated pattern having a shape extending in one direction in the plan view. The insulating layer 41 has a pair of side surfaces facing each other in a cross-sectional view. The transistor M2 is provided along the side surface of the insulating layer 41 on the connection portion CO side, and the transistor MI is provided along the opposite side surface.

The conductive layer 51 and the conductive layer 52 are provided over the insulating layer 11, and the insulating layer 43 and the conductive layer 55 are provided over the conductive layer 52. The insulating layer 41 is provided to cover the end portion of the conductive layer 55 and the insulating layer 43, and the conductive layer 53 and the conductive layer 54 are provided over the insulating layer 41.

In each of the insulating layer 41, the conductive layer 53, and the conductive layer 54, part of the side surface on the connection portion CO side overlaps with the conductive layer 55. The semiconductor layer 21B of the transistor M2 is provided in contact with the side surface of the insulating layer 41. The insulating layer 22B and the conductive layer 56 are provided to cover the semiconductor layer 21B.

In each of the insulating layer 43, the insulating layer 41, and the conductive layer 56, part of the side surface opposite to the connection portion CO overlaps with the wiring SL. The semiconductor layer 21A of the transistor MI is provided in contact with the side surface of the insulating layer 41. The insulating layer 22A, the conductive layer 57, and the conductive layer 58 are provided to cover the semiconductor layer 21A.

Placing the transistors on the pair of side surfaces of the insulating layer 41 in this manner can reduce the distance between the two transistors. This enables transistor arrangement with higher density. For example, three or more transistors can be arranged with the same resolution.

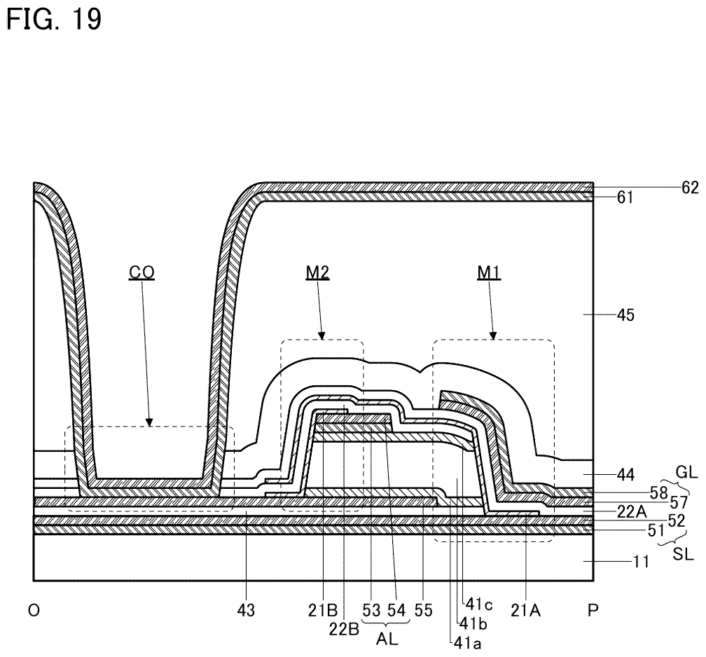

FIG. 19 illustrates an example in which the conductive layer 56 is not provided and the semiconductor layer 21A also serves as the gate electrode of the transistor M2. Consequently, the manufacturing process can be simplified and productivity can be improved.

The above is the description of the structure examples of the display devices.

According to the semiconductor device of one embodiment of the present invention, a device in which transistors with high electrical characteristics and high reliability are integrated with extremely high density can be provided. According to one embodiment of the present invention, with the use of a manufacturing apparatus for a general flat panel display, a display device with a resolution over 3000 ppi, which has been difficult to achieve, can be obtained.

At least part of the structure examples, the drawings corresponding thereto, and the like described in this embodiment can be combined with the other structure examples, the other drawings, and the like as appropriate.

### Embodiment 2

In this embodiment, a display device using the semiconductor device of one embodiment of the present invention will be described with reference to the drawings.

The display device of this embodiment can be a high-resolution display device. Accordingly, the display device of this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The display device of this embodiment can be a high-definition display device or a large-sized display device. Accordingly, the display device of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

The semiconductor device of one embodiment of the present invention can be used for a display device or a module including the display device. Examples of the module including the display device include a module in which a connector such an FPC or a TCP is attached to the display device and a module in which the display device is mounted with an IC by a COG method, a COF method, or the like.

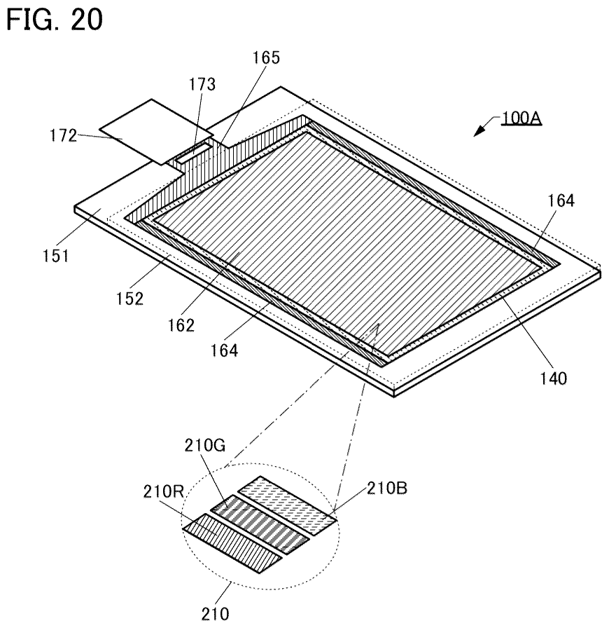

FIG. 20 is a perspective view of a display device 100A.

In the display device 100A, a substrate 152 and a substrate 151 are bonded to each other. In FIG. 20, the substrate 152 is indicated by a dashed line.

The display device 100A includes a display portion 162, a connection portion 140, a circuit portion 164, a wiring 165, and the like. FIG. 20 illustrates an example in which an IC 173 and an FPC 172 are implemented onto the display device 100A. Thus, the structure illustrated in FIG. 20 can be regarded as a display module including the display device 100A, the IC, and the FPC.

The connection portion 140 is provided outside the display portion 162. The connection portion 140 can be provided along one or more sides of the display portion 162. The number of connection portions 140 may be one or more. FIG. 20 illustrates an example where the connection portion 140 is provided to surround the four sides of the display portion 162. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The wiring 165 has a function of supplying a signal and power to the display portion 162 and the circuit portion 164. The signal and power are input to the wiring 165 from the outside through the FPC 172 or from the IC 173.

FIG. 20 illustrates an example where the IC 173 is provided on the substrate 151 by a COG method, a COF method, or the like. An IC including one or both of a scan line driver circuit and a signal line driver circuit can be used as the IC 173, for example. Note that the display device 100A and the display module are not necessarily provided with an IC. The IC may be mounted on the FPC by a COF method or the like.

The semiconductor device of one embodiment of the present invention can be used for one or both of the display portion 162 and the circuit portion 164 of the display device 100A, for example. The semiconductor device of one embodiment of the present invention can also be used for the IC 173. A structure where the vertical transistor of one embodiment of the present invention is provided over a silicon wafer can be employed, for example. In that case, it is preferable to form the circuit using two types of transistors, in which a transistor including single crystal silicon in a semiconductor layer is provided and the vertical transistor of one embodiment of the present invention is stacked above the transistor.

When the semiconductor device of one embodiment of the present invention is used for a pixel circuit of the display device, the area occupied by the pixel circuit can be reduced as compared with the case where a planar transistor is used, and thus the display device can have high resolution, for example. When the semiconductor device of one embodiment of the present invention is used for a driver circuit (e.g., one or both of a gate line driver circuit and a source line driver circuit) of the display device, the area occupied by the driver circuit can be reduced as compared with the case where a planar transistor is used, and thus the display device can have a narrow bezel, for example. Since the semiconductor device of one embodiment of the present invention has favorable electrical characteristics, a display device can have increased reliability by using the semiconductor device.

The display portion 162 of the display device 100A is a region where an image is to be displayed, and includes a plurality of pixels 210 that are periodically arranged. FIG. 20 illustrates an enlarged view of one pixel 210.

There is no particular limitation on the arrangement of the pixels in the display device of this embodiment, and any of a variety of arrangements can be employed. Examples of the arrangement of the pixels include stripe arrangement, S-stripe arrangement, matrix arrangement, delta arrangement, Bayer arrangement, and PenTile arrangement.

The pixel 210 illustrated in FIG. 20 includes a subpixel 210R that emits red light, a subpixel 210G that emits green light, and a subpixel 210B that emits blue light.

Any of a variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (quantum-dot LED) employing a light source and color conversion technology using quantum dot materials may be used.

Examples of a display device including a liquid crystal element include a transmissive liquid crystal display device, a reflective liquid crystal display device, and a transflective liquid crystal display device.

Examples of light-emitting elements are self-luminous type light-emitting elements such as an LED (Light Emitting Diode), an OLED (Organic LED), and a semiconductor laser. As the LED, for example, a mini LED, a micro LED, or the like can be used.

Examples of a light-emitting substance included in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

The light-emitting element can emit infrared, red, green, blue, cyan, magenta, yellow, or white light, for example. When the light-emitting element has a microcavity structure, higher color purity can be achieved.

One of the pair of electrodes of the light-emitting element functions as an anode, and the other electrode functions as a cathode. The display device of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

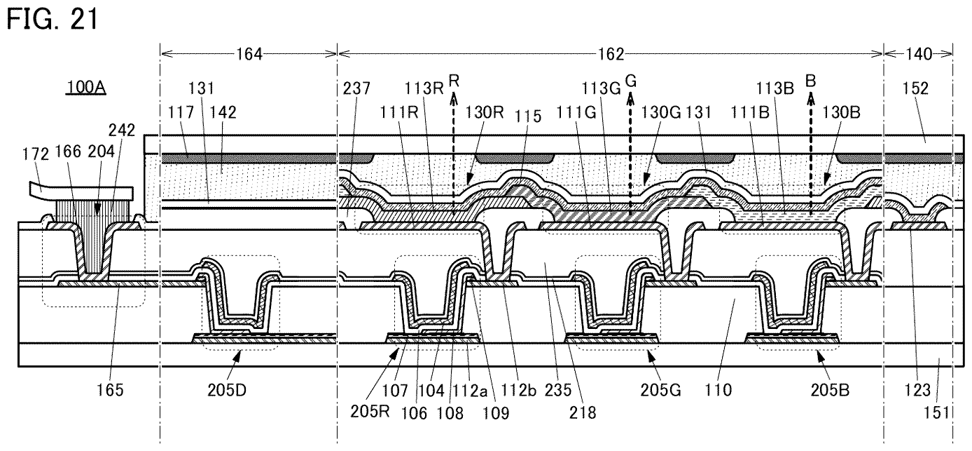

FIG. 21 illustrates an example of cross sections of part of a region including the FPC 172, part of the circuit portion 164, part of the display portion 162, part of the connection portion 140, and part of a region including the end portion of the display device 100A.

The display device 100A illustrated in FIG. 21 includes transistors 205D, 205R, 205G, and 205B, a light-emitting element 130R, a light-emitting element 130G, a light-emitting element 130B, and the like between the substrate 151 and the substrate 152. The light-emitting elements 130R, 130G, and 130B are display elements included in the subpixel 210R that emits red light, the subpixel 210G that emits green light, and the subpixel 210B that emits blue light, respectively.

The display device 100A employs an SBS (Side By Side) structure. The SBS structure can optimize materials and structures of light-emitting elements and thus can extend freedom of choice of materials and structures, whereby the luminance and the reliability can be easily improved.

The display device 100A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

All of the transistors 205D, 205R, 205G, and 205B are formed on a sidewall of a slit provided in the insulating layer 110 over the substrate 151. These transistors can be manufactured using the same process.

This embodiment shows an example in which the vertical transistor of one embodiment of the present invention, which uses an oxide semiconductor in the semiconductor and can be easily highly integrated, are used as transistors 205D, 205R, 205G, and 205B. The transistors 205R, 205G, and 205B function as, for example, driving transistors controlling current flowing through the light-emitting elements. The transistor 205D provided in the circuit portion 164 form part of the driver circuit. The transistor of one embodiment of the present invention has both a high on-state current and a low off-state current, and thus can be used not only in a gate line driver circuit but also in a source line driver circuit.

Specifically, each of the transistors 205D, 205R, 205G, and 205B is provided along one side surface that is of an insulating layer provided with a slit and positioned in the slit, and each transistor includes a conductive layer 104 functioning as a gate electrode, an insulating layer 106 functioning as a gate insulating layer, a conductive layer 109 functioning as one of a source electrode and a drain electrode, a conductive layer 107 functioning as the other of the source electrode and the drain electrode, a semiconductor layer 108, and the like. The conductive layer 109 and the conductive layer 107 are in contact with the semiconductor layer 108. In addition, a conductive layer 112a in contact with the conductive layer 107 and a conductive layer 112b in contact with the conductive layer 109 are provided. Each of the conductive layer 112a and the conductive layer 112b includes a conductive material having lower resistance than the conductive layer 107 and the conductive layer 109 and serves as a wiring. Here, a plurality of layers obtained by processing one film are shown with the same hatching pattern.

As described above, the display device 100A includes any of the transistors of embodiments of the present invention in both the display portion 162 and the circuit portion 164. When the display portion 162 includes the transistor of one embodiment of the present invention, the pixel size can be reduced and high resolution can be achieved. When the circuit portion 164 includes the transistor of one embodiment of the present invention, the area occupied by the circuit portion 164 can be reduced and a narrower bezel can be achieved. When one or both of the display portion 162 and the circuit portion 164 include the transistors of one embodiment of the present invention, the load of wirings can be reduced; thus, a display device capable of high-speed operation, a large-sized display device, or a display device with high definition (with a large number of pixels) can be achieved. The description in the above embodiment can be referred to for the transistor of one embodiment of the present invention.

Note that the transistor included in the display device of this embodiment is not limited to the transistor of one embodiment of the present invention. For example, the display device of this embodiment may include the transistor of one embodiment of the present invention and a transistor having another structure in combination.

The display device of this embodiment may include one or more of a planar transistor, a staggered transistor, and an inverted staggered transistor. A transistor included in the display device of this embodiment may have a top-gate structure or a bottom-gate structure. Gates may be provided above and below a semiconductor layer where a channel is formed.

A transistor including silicon in its channel formation region (a Si transistor) may be included in the display device of this embodiment. Examples of silicon include single crystal silicon, polycrystalline silicon, and amorphous silicon. In particular, a transistor containing LTPS (Low Temperature Poly Silicon) in its semiconductor layer (hereinafter also referred to as an LTPS transistor) can be used. The LTPS transistor has high field-effect mobility and excellent frequency characteristics. The transistor containing amorphous silicon in the semiconductor layer, which can be uniformly formed over a large-area glass substrate, is excellent in productivity.

The display device of this embodiment may include a transistor using an oxide semiconductor typified by an In—Ga—Zn oxide (also referred to as IGZO) in the channel formation region (an OS transistor). For example, both a transistor containing silicon in its semiconductor where a channel is formed and a transistor containing an oxide semiconductor may be included in the display device.

The transistor included in the circuit portion 164 and the transistor included in the display portion 162 may have the same structure or different structures. One structure or two or more kinds of structures may be employed for a plurality of transistors included in the circuit portion 164. Similarly, one structure or two or more kinds of structures may be employed for a plurality of transistors included in the display portion 162.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high drive capability. Note that a structure in which an LTPS transistor and an OS transistor are used in combination is referred to as LTPO in some cases. As a favorable example, a structure is given in which an OS transistor is used as a transistor functioning as a switch for controlling electrical continuity and discontinuity between wirings and an LTPS transistor is used as a transistor for controlling a current.

For example, one transistor included in the display portion 162 functions as a transistor for controlling a current flowing through the light-emitting element and can also be referred to as a driving transistor. One of a source and a drain of the driving transistor is electrically connected to a pixel electrode of the light-emitting element.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

An insulating layer 218 is provided to cover the transistors 205D, 205R, 205G, and 205B and an insulating layer 235 is provided over the insulating layer 218.

The insulating layer 218 preferably functions as a protective layer of the transistors. A material that does not easily allow diffusion of impurities such as water and hydrogen is preferably used for the insulating layer 218. This is because the insulating layer 218 can function as a barrier layer. Such a structure can effectively inhibit diffusion of impurities into the transistors from the outside and increase the reliability of the display device.

The insulating layer 218 preferably includes one or more inorganic insulating films. Examples of the inorganic insulating film include an oxide insulating film, a nitride insulating film, an oxynitride insulating film, and a nitride oxide insulating film. Specific examples of these inorganic insulating films are as described above.

The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. In that case, the formation of a depression in the insulating layer 235 can be inhibited in processing pixel electrodes 111R, 111G, and 111B, for example. Alternatively, a depression may be formed in the insulating layer 235 in processing the pixel electrodes 111R, 111G, and 111B, for example.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 21 emits red light (R). The EL layer 113R includes a light-emitting layer that emits red light.

In a similar manner, the light-emitting element 130G includes the pixel electrode 111G, an EL layer 113G, and the common electrode 115. The light-emitting element 130G emits green light (G) and the EL layer 113G includes a light-emitting layer that emits green light.

In a similar manner, the light-emitting element 130B includes the pixel electrode 111B, an EL layer 113B, and the common electrode 115. The light-emitting element 130B emits blue light (B) and the EL layer 113B includes a light-emitting layer that emits blue light.

Although the EL layers 113R, 113G, and 113B have the same thickness in FIG. 21, the present invention is not limited thereto. The EL layers 113R, 113G, and 113B may have different thicknesses. For example, the thicknesses of the EL layers 113R, 113G, and 113B are preferably set to match an optical path length that intensifies light emitted from each EL layer. In that case, a microcavity structure is obtained, and the color purity of light emitted from each light-emitting element can be improved.

The pixel electrode 111R is electrically connected to the conductive layer 112b included in the transistor 205R through an opening provided in the insulating layer 106, the insulating layer 218, and the insulating layer 235. In a similar manner, the pixel electrode 111G is electrically connected to the conductive layer 112b included in the transistor 205G and the pixel electrode 111B is electrically connected to the conductive layer 112b included in the transistor 205B.

End portions of the pixel electrodes 111R, 111G, and 111B are covered with an insulating layer 237. The insulating layer 237 functions as a partition wall (also referred to as an embankment, a bank, or a spacer). The insulating layer 237 can have a single-layer structure or a stacked-layer structure including one or both of an inorganic insulating material and an organic insulating material. A material that can be used for the insulating layer 218 and a material that can be used for the insulating layer 235 can be used for the insulating layer 237, for example. The insulating layer 237 can electrically isolate the pixel electrode and the common electrode. Furthermore, the insulating layer 237 can electrically isolate light-emitting elements adjacent to each other.

The common electrode 115 is one continuous film shared by the light-emitting elements 130R, 130G, and 130B. The common electrode 115 shared by the light-emitting elements is electrically connected to a conductive layer 123 provided in the connection portion 140. The conductive layer 123 is preferably formed using a conductive layer formed using the same material through the same process as the pixel electrodes 111R, 111G, and 111B.

In the display device of one embodiment of the present invention, a conductive film that transmits visible light is used for the electrode through which light is extracted, which is either the pixel electrode or the common electrode. A conductive film reflecting visible light is preferably used for the electrode through which light is not extracted.

A conductive film that transmits visible light may be used also for the electrode through which light is not extracted. In that case, this electrode is preferably provided between a reflective layer and the EL layer. In other words, light emitted by the EL layer may be reflected by the reflective layer to be extracted from the display device.

As the material of the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium (Mg—Ag) and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Therefore, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode preferably has a light transmittance as high as possible; for example, the light transmittance is higher than or equal to 40% and lower than or equal to 100%. For example, an electrode having a visible light (light with wavelengths greater than or equal to 400 nm and less than 750 nm) transmittance higher than or equal to 40% and less than or equal to 100% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity as low as possible; for example, less than or equal to 1×10⁻² Ωcm is preferable.

The EL layers 113R, 113G, and 113B are each provided to have an island shape. In FIG. 21, an end portion of the EL layer 113R and an end portion of the EL layer 113G adjacent to each other overlap with each other, an end portion of the EL layer 113G and an end portion of the EL layer 113B adjacent to each other overlap with each other, and an end portion of the EL layer 113R and an end portion of the EL layer 113B adjacent to each other overlap with each other. When island-shaped EL layers are formed using a fine metal mask, end portions of the EL layers adjacent to each other may overlap with each other as illustrated in FIG. 21; however, the present invention is not limited thereto. That is, it is also possible that the EL layers adjacent to each other do not overlap with each other and are apart from each other. It is also possible that the display device includes both a portion where the EL layers adjacent to each other overlap with each other and a portion where the EL layers adjacent to each other do not overlap with each other and are apart from each other.

Each of the EL layers 113R, 113G, and 113B includes at least a light-emitting layer. The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (also referred to as a substance with a high electron-transport property and a high hole-transport property or a bipolar material) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further include one or both of a bipolar material and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. A tandem structure enables a light-emitting element capable of emitting light with high luminance. Furthermore, the amount of current needed for obtaining a predetermined luminance can be smaller in a tandem structure than in a single structure; thus, a tandem structure enables higher reliability. A tandem structure may be referred to as a stack structure.

In the case of using a tandem light-emitting element in FIG. 21, the EL layer 113R preferably includes a plurality of light-emitting units that emit red light, the EL layer 113G preferably includes a plurality of light-emitting units that emit green light, and the EL layer 113B preferably includes a plurality of light-emitting units that emit blue light.

A protective layer 131 is provided over the light-emitting elements 130R, 130G, and 130B. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting elements. In FIG. 21, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In that case, the adhesive layer 142 may be provided not to overlap with the light-emitting element. Furthermore, the space may be filled with a resin other than the frame-shaped adhesive layer 142.

The protective layer 131 is provided at least in the display portion 162, and preferably provided to cover the entire display portion 162. By providing the protective layer 131 over the light-emitting elements 130R, 130G, and 130B, the reliability of the light-emitting elements can be increased. The protective layer 131 is preferably provided to cover not only the display portion 162 but also the connection portion 140 and the circuit portion 164. It is also preferable that the protective layer 131 be provided to extend to an end portion of the display device 100A. Meanwhile, a connection portion 204 has a portion not provided with the protective layer 131 so that the FPC 172 and a conductive layer 166 are electrically connected to each other.

The protective layer 131 may have a single-layer structure or a stacked-layer structure of two or more layers. There is no limitation on the conductivity of the protective layer 131. For the protective layer 131, at least one of an insulating film, a semiconductor film, and a conductive film can be used. The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved. For the protective layer 131, an inorganic insulating film such as an oxide insulating film, a nitride insulating film, an oxynitride insulating film, or a nitride oxide insulating film can be used, for example. Specific examples of these inorganic insulating films are as described above. In particular, the protective layer 131 preferably includes a nitride insulating film or a nitride oxide insulating film, and further preferably includes a nitride insulating film.

An inorganic film containing ITO, In—Zn oxide, Ga—Zn oxide, Al—Zn oxide, IGZO, or the like can be used for the protective layer 131. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can be, for example, a stack of an aluminum oxide film and a silicon nitride film over the aluminum oxide film, or a stack of an aluminum oxide film and an IGZO film over the aluminum oxide film. Such a stacked-layer structure can inhibit entry of impurities (e.g., water and oxygen) into the EL layer side.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 204 is provided in a region of the substrate 151 not overlapping with the substrate 152. In the connection portion 204, the wiring 165 is electrically connected to the FPC 172 through the conductive layer 166 and a connection layer 242. In this example, the wiring 165 is a conductive layer obtained by processing the same conductive film as the conductive layer 112b. In this example, the conductive layer 166 is a conductive layer obtained by processing the same conductive film as the pixel electrodes 111R, 111G, and 111B. On the top surface of the connection portion 204, the conductive layer 166 is exposed. Thus, the connection portion 204 and the FPC 172 can be electrically connected to each other through the connection layer 242.

The display device 100A has a top-emission structure. Light from the light-emitting element is emitted toward the substrate 152. For the substrate 152, a material having a high visible-light-transmitting property is preferably used. The pixel electrodes 111R, 111G, and 111B contain a material that reflects visible light, and the counter electrode (the common electrode 115) contains a material that transmits visible light.

The light-blocking layer 117 is preferably provided on the surface of the substrate 152 on the substrate 151 side. The light-blocking layer 117 can be provided between adjacent light-emitting elements, in the connection portion 140, in the circuit portion 164, and the like.

A coloring layer such as a color filter may be provided on the surface of the substrate 152 on the substrate 151 side or over the protective layer 131. When the color filter is provided so as to overlap with the light-emitting element, the color purity of light emitted from the pixel can be increased.

Moreover, a variety of optical members can be provided on the outer surface of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 152. For example, a glass layer or a silica layer (SiOₓ layer) is preferably provided as the surface protective layer to inhibit the surface contamination and generation of a scratch. For the surface protective layer, DLC (diamond-like carbon), aluminum oxide (AlOₓ), a polyester-based material, a polycarbonate-based material, or the like may be used. The surface protective layer is preferably formed using a material having high visible light transmittance. The surface protective layer is preferably formed using a material with high hardness.

For each of the substrate 151 and the substrate 152, glass, quartz, ceramics, sapphire, a resin, a metal, an alloy, a semiconductor, or the like can be used. For the substrate on the side from which light from the light-emitting element is extracted, a material that transmits the light is used. When the substrate 151 and the substrate 152 are formed using a flexible material, the flexibility of the display device can be increased and a flexible display can be achieved. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used for at least one of the substrate 151 and the substrate 152.

In the case where a circularly polarizing plate overlaps with the display device, a highly optically isotropic substrate is preferably used as the substrate included in the display device. A highly optically isotropic substrate has a low birefringence (in other words, a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

As the connection layer 242, an anisotropic conductive film (ACF), an anisotropic conductive paste (ACP), or the like can be used.

### Display Device 100b

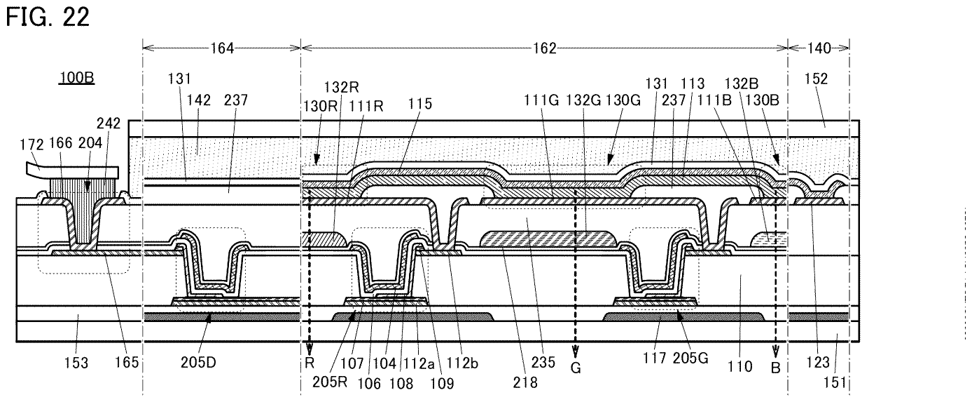

A display device 100B illustrated in FIG. 22 is different from the display device 100A mainly in a bottom-emission display device and in including an EL layer 113 shared by the light-emitting elements and coloring layers (color filters or the like) in the subpixels of different colors. Note that in the following description of display devices, the description of portions similar to those of the above-described display device may be omitted.

Light from the light-emitting element is emitted toward the substrate 151. For the substrate 151, a material having a high visible-light-transmitting property is preferably used. By contrast, there is no limitation on the light-transmitting property of a material used for the substrate 152.

In the display device 100B illustrated in FIG. 22, the transistor 205D, the transistor 205R, the transistor 205G, the transistor 205B (not illustrated), the light-emitting elements 130R, 130G, and 130B, a coloring layer 132R transmitting red light, a coloring layer 132G transmitting green light, a coloring layer 132B transmitting blue light, and the like are provided between the substrate 151 and the substrate 152.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display device 100B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display device 100B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display device 100B through the coloring layer 132B.

The EL layer 113 and the common electrode 115 are shared between the light-emitting elements 130R, 130G, and 130B. The number of manufacturing processes can be smaller in the case where the EL layer 113 is shared between the subpixels of different colors than the case where the subpixels of different colors include different EL layers.

The light-emitting elements 130R, 130G, and 130B illustrated in FIG. 22 emit white light, for example. When white light emitted from the light-emitting elements 130R, 130G, and 130B passes through the coloring layers 132R, 132G, and 132B, light of desired colors can be obtained.

The light-blocking layer 117 is preferably formed between the substrate 151 and the transistor. FIG. 22 illustrates an example where the light-blocking layer 117 are provided over the substrate 151, an insulating layer 153 is provided over the light-blocking layer 117, and the transistor 205D, the transistor 205R, the transistor 205G, the transistor 205B (not illustrated), and the like are provided over the insulating layer 153. In addition, the coloring layer 132R, the coloring layer 132G, and the coloring layer 132B are provided over the insulating layer 218 and the insulating layer 235 is provided over the coloring layer 132R, the coloring layer 132G, and the coloring layer 132B.

A material having a high visible-light-transmitting property is used for each of the pixel electrodes 111R, 111G, and 111B. A material that reflects visible light is preferably used for the common electrode 115. In the bottom-emission display device, a metal or the like having low resistance can be used for the common electrode 115; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display device having a bottom-emission structure.

In the case of employing a microcavity structure, the light-emitting elements 130R, 130G, and 130B each emit light with a specific wavelength, which is intensified, in white light emitted from the EL layer 113. Here, even with such a microcavity structure, a light-emitting element including an EL layer that emits white light is referred to as a white-light-emitting element.

In the light-emitting element that emits white light, two or more light-emitting layers are preferably included. When two light-emitting layers are used to obtain white light, two light-emitting layers that emit light of complementary colors are selected. For example, when the emission colors of the first light-emitting layer and the second light-emitting layer are made complementary, the light-emitting element can be configured to emit white light as a whole. In the case where three or more light-emitting layers are used to obtain white light, the light-emitting element is configured to emit white light as a whole by combining emission colors of the three or more light-emitting layers.

For example, the EL layer 113 preferably includes a light-emitting layer containing a light-emitting substance that emits blue light and a light-emitting layer containing a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red light and green light and a light-emitting unit that emits blue light; a three-unit tandem structure in which a light-emitting unit that emits blue light, a light-emitting unit that emits yellow, yellow-green, or green light, and a light-emitting unit that emits blue light are stacked in this order; and a three-unit tandem structure in which a light-emitting unit that emits blue light, a light-emitting unit that emits yellow, yellow-green, or green light and red light, and a light-emitting unit that emits blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Alternatively, the light-emitting elements 130R, 130G, and 130B illustrated in FIG. 22 may emit blue light, for example. In this case, the EL layer 113 includes one or more light-emitting layers that emit blue light. In the subpixel 210B that emits blue light, blue light emitted from the light-emitting element 130B can be extracted. In each of the subpixel 210R that emits red light and the subpixel 210G that emits green light, a color conversion layer is provided between the light-emitting element 130R or the light-emitting element 130G and the substrate 151 so that blue light emitted from the light-emitting element 130R or 130G is converted into light with a longer wavelength, whereby red light or green light can be extracted. Furthermore, it is preferable that the coloring layer 132R be provided between the color conversion layer and the substrate 151 on an optical path of light emitted by the light-emitting element 130R, and the coloring layer 132G be provided between the color conversion layer and the substrate 151 on an optical path of light emitted by the light-emitting element 130G. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

### Display Device 100c

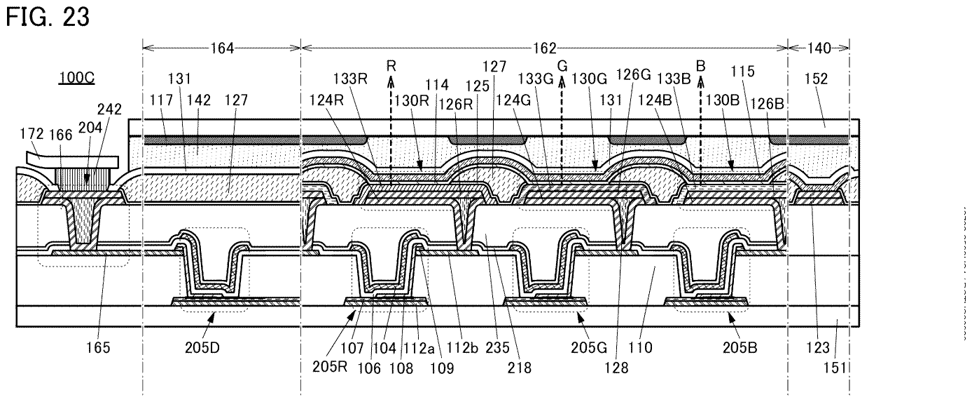

A display device 100C illustrated in FIG. 23 is an example of a display device having an MML (metal maskless) structure. In other words, the display device 100C includes a light-emitting element that is formed without using a fine metal mask. The stacked-layer structure from the substrate 151 to the insulating layer 235 and the stacked-layer structure from the protective layer 131 to the substrate 152 are similar to those in the display device 100A; therefore, description thereof is omitted.

In FIG. 23, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 23 emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

Similarly, the light-emitting element 130G includes a conductive layer 124G, a conductive layer 126G, a layer 133G, the common layer 114, and the common electrode 115. The layer 133G includes a light-emitting layer that emits green light (G).

Similarly, the light-emitting element 130B includes a conductive layer 124B, a conductive layer 126B, a layer 133B, the common layer 114, and the common electrode 115. The layer 133B includes a light-emitting layer that emits blue light (B).

In this specification and the like, in the EL layers included in the light-emitting elements, the island-shaped layer provided in each light-emitting element is referred to as the layer 133B, the layer 133G, or the layer 133R, and the layer shared by the light-emitting elements is referred to as the common layer 114. Note that in this specification and the like, only the layer 133R, the layer 133G, and the layer 133B are sometimes referred to as island-shaped EL layers, EL layers formed in an island shape, or the like, in which case the common layer 114 is not included in the EL layer.

The layer 133R, the layer 133G, and the layer 133B are isolated from each other. When the EL layer is provided to have an island shape for each light-emitting element, a leakage current between adjacent light-emitting elements can be inhibited. This can prevent crosstalk due to unintended light emission, so that a display device with extremely high contrast can be obtained.

Although the layers 133R, 133G, and 133B have the same thickness in FIG. 23, the layers 133R, 133G, and 133B may have different thicknesses.

The conductive layer 124R is electrically connected to the conductive layer 112b included in the transistor 205R through an opening provided in the insulating layer 106, the insulating layer 218, and the insulating layer 235. In a similar manner, the conductive layer 124G is electrically connected to the conductive layer 112b included in the transistor 205G and the conductive layer 124B is electrically connected to the conductive layer 112b included in the transistor 205B.

The conductive layers 124R, 124G, and 124B are formed to cover the openings provided in the insulating layer 235. A layer 128 is embedded in each of the depressions of the conductive layers 124R, 124G, and 124B.

The layer 128 has a function of filling the depressions of the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128.

Here, the layers 133R, 133G, and 133B are formed by processing with a photolithography method. Thus, in the case where the layer 128 is not used and the conductive layer 126R, the conductive layer 126G, and the conductive layer 126B are not provided, films to be the layers 133R, 133G, and 133B are formed also in the depressions of the conductive layers 124R, 124G, and 124B. At this time, the film positioned in the depression is not etched and a residue might be collected. Thus, the formation surfaces of the layers 133R, 133G, and 133B are preferably planarized with the layer 128 and the conductive layers 126R, 126G, and 126B.

Here, the portion where the layer 128 is provided is covered with insulating layers 125 and 127 so as to be a non-light-emitting region; however, with a structure in which the layer 128 is not covered with the insulating layers 125 and 127, a region overlapping with the depressions of the conductive layers 124R, 124G, and 124B can also be used as the light-emitting region, and thus the aperture ratio of the pixels can be increased. The conductive layer 124R and the conductive layer 126R each preferably include a conductive layer functioning as a reflective electrode.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 23 illustrates an example where the top surface of the layer 128 includes a flat portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle less than 90°. In the case where the end portions of the pixel electrodes have a tapered shape, the layer 133R provided along the side surfaces of the pixel electrodes has an inclined portion. When the side surface of the pixel electrode has a tapered shape, coverage with an EL layer provided along the side surface of the pixel electrode can be improved.

Since the conductive layers 124G and 126G and the conductive layers 124B and 126B are similar to the conductive layers 124R and 126R, the detailed description thereof is omitted.

The top surface and a side surface of the conductive layer 126R are covered with the layer 133R. Similarly, the top surface and a side surface of the conductive layer 126G are covered with the layer 133G, and the top surface and a side surface of the conductive layer 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layers 133R, 133G, and 133B are covered with the insulating layers 125 and 127. The common layer 114 is provided over the layers 133R, 133G, and 133B, and the insulating layers 125 and 127, and the common electrode 115 is provided over the common layer 114. The common layer 114 and the common electrode 115 are each a continuous film provided to be shared by a plurality of light-emitting elements.

In FIG. 23, the insulating layer 237 illustrated in FIG. 21 and the like is not provided between the conductive layer 126R and the layer 133R. That is, an insulating layer (also referred to as a partition wall, a bank, a spacer, or the like) in contact with the pixel electrode and covering an upper end portion of the pixel electrode is not provided in the display device 100C. Thus, the interval between adjacent light-emitting elements can be extremely shortened. Accordingly, the display device can have high resolution or high definition. In addition, a mask for forming the insulating layer is not needed, which leads to a reduction in manufacturing cost of the display device.

As described above, the layers 133R, 133G, and 133B each include the light-emitting layer. The layers 133R, 133G, and 133B each preferably include the light-emitting layer and a carrier-transport layer (an electron-transport layer or a hole-transport layer) over the light-emitting layer. Alternatively, the layers 133R, 133G, and 133B each preferably include a light-emitting layer and a carrier-blocking layer (a hole-blocking layer or an electron-blocking layer) over the light-emitting layer. Alternatively, the layers 133R, 133G, and 133B each preferably include a light-emitting layer, a carrier-blocking layer over the light-emitting layer, and a carrier-transport layer over the carrier-blocking layer. Since surfaces of the layers 133R, 133G, and 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, a carrier-injection layer (an electron-injection layer or a hole-injection layer). Alternatively, the common layer 114 may be a stack of an electron-transport layer and an electron-injection layer, or may be a stack of a hole-transport layer and a hole-injection layer. The common layer 114 is shared by the light-emitting elements 130R, 130G, and 130B.

Note that in the case where the layers 133R, 133G, and 133B each include a light-emitting layer, a carrier-transport layer over the light-emitting layer, and a carrier-injection layer over the carrier-transport layer, the common layer 114 is not necessarily provided. In that case, the common electrode 115 is provided in contact with the layer 133R, the layer 133G, the layer 133B, the insulating layer 127, the insulating layer 125, and the like.

The side surfaces of the layers 133R, 133G, and 133B are each covered with the insulating layer 125. The insulating layer 127 covers the side surfaces of the layers 133R, 133G, and 133B with the insulating layer 125 therebetween.

The side surface (and part of the top surface) of each of the layers 133R, 133G, and 133B are covered with at least one of the insulating layer 125 and the insulating layer 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 is preferably in contact with the side surfaces of the layers 133R, 133G, and 133B. The insulating layer 125 in contact with the layers 133R, 133G, and 133B can prevent film separation of the layers 133R, 133G, and 133B, whereby the reliability of the light-emitting element can be increased.

The insulating layer 127 is provided over the insulating layer 125 to fill a depression of the insulating layer 125. The insulating layer 127 preferably covers at least part of the side surface of the insulating layer 125.

The insulating layer 125 and the insulating layer 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layers 133R, 133G, and 133B, the insulating layer 125, and the insulating layer 127. Before the insulating layer 125 and the insulating layer 127 are provided, a step is generated due to a level difference between a region where the pixel electrode and the island-shaped EL layer are provided and a region where neither the pixel electrode nor the island-shaped EL layer is provided (a region between the light-emitting elements). In the display device of one embodiment of the present invention, the step can be eliminated with the insulating layer 125 and the insulating layer 127, and the coverage with the common layer 114 and the common electrode 115 can be improved. Thus, poor connection caused by step disconnection can be inhibited. In addition, an increase in electric resistance, which is caused by local thinning of the common electrode 115 due to the step, can be inhibited.

The top surface of the insulating layer 127 preferably has a shape with high flatness. The top surface of the insulating layer 127 may include at least one of a flat surface, a convex surface, and a concave surface. For example, the top surface of the insulating layer 127 preferably has a smooth convex shape with high flatness.

The insulating layer 125 can be formed using an inorganic material. For the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 may have a single-layer structure or a stacked-layer structure. In particular, aluminum oxide is preferable because it has high selectivity with respect to the EL layer in etching and has a function of protecting the EL layer in formation of the insulating layer 127. In particular, when an inorganic insulating film such as an aluminum oxide film, a hafnium oxide film, or a silicon oxide film is formed by an ALD method as the insulating layer 125, the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen.

Note that in this specification and the like, a barrier insulating layer refers to an insulating layer having a barrier property. A barrier property in this specification and the like refers to a function of inhibiting diffusion of a targeted substance (also referred to as having low permeability).

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has a sufficiently low hydrogen concentration or a sufficiently low carbon concentration, and further preferably has both a sufficiently low hydrogen concentration and a sufficiently low carbon concentration.

The insulating layer 127 provided over the insulating layer 125 has a function of filling large unevenness of the insulating layer 125, which is formed between the adjacent light-emitting elements. In other words, the insulating layer 127 has an effect of improving the planarity of the formation surface of the common electrode 115.

As the insulating layer 127, an insulating layer containing an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymer in a broad sense in some cases.

Alternatively, the insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. The insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive organic resin. As the photosensitive organic resin, either a positive-type material or a negative-type material may be used.

The insulating layer 127 may be formed using a material absorbing visible light. When the insulating layer 127 absorbs light emitted from the light-emitting element, light leakage (stray light) from the light-emitting element to the adjacent light-emitting element through the insulating layer 127 can be suppressed. Thus, the display quality of the display device can be improved. Since no polarizing plate is required to improve the display quality of the display device, the weight and thickness of the display device can be reduced.

Examples of the material absorbing visible light include a material containing a pigment of black or any other color, a material containing a dye, a light-absorbing resin material (e.g., polyimide), and a resin material that can be used for color filters (a color filter material). Using a resin material obtained by stacking or mixing color filter materials of two or three or more colors is particularly preferred to enhance the effect of blocking visible light. In particular, mixing color filter materials of three or more colors enables the formation of a black or nearly black resin layer.

### Display Device 100D

A liquid crystal display device where liquid crystal elements are used as display elements is described below.

Any of elements with various structures can be used as the liquid crystal elements included in the display device. Typically, a liquid crystal element employing a vertical alignment (VA) mode, a fringe field switching (FFS) mode, an in-plane switching (IPS) mode, or the like can be used. Although a transmissive liquid crystal element is preferably used as the liquid crystal element, a reflective or transflective liquid crystal element may be used. The display device is preferably a normally black liquid crystal display device.

Examples of the VA mode include a multi-domain vertical alignment (MVA) mode, a patterned vertical alignment (PVA) mode, and an advanced super view (ASV) mode.

As the liquid crystal element, a liquid crystal element employing any of a variety of modes can be used. A liquid crystal element can employ, for example, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, a guest-host mode, or the like in addition to a VA mode, an FFS mode, and an IPS mode.

Here, the liquid crystal display device is a display device that controls transmission and non-transmission of light by utilizing polarized light and an optical modulation action of a liquid crystal. The optical modulation action of the liquid crystal is controlled by an electric field applied to the liquid crystal (including a horizontal electric field, a vertical electric field, and an oblique electric field). As a liquid crystal that can be used for the liquid crystal element, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, an anti-ferroelectric liquid crystal, and the like can be used. These liquid crystal materials exhibit a cholesteric phase, a smectic phase, a cubic phase, a chiral nematic phase, an isotropic phase, or the like depending on conditions. As the liquid crystal material, either a positive liquid crystal or a negative liquid crystal may be used, and an appropriate liquid crystal material can be used depending on the mode or design to be used.

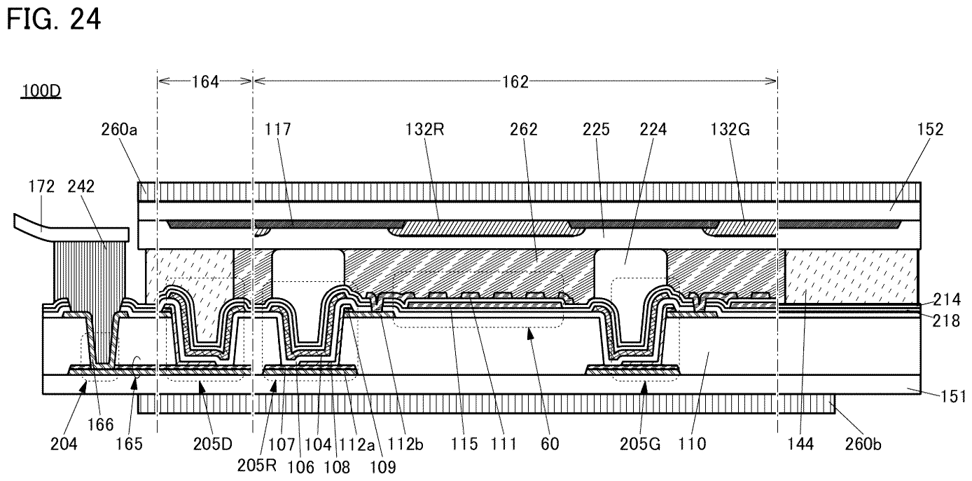

A display device 100D illustrated in FIG. 24 is a liquid crystal display device in an FFS mode.

The substrate 151 and the substrate 152 are bonded to each other with an adhesive layer 144. A liquid crystal 262 is sealed in a region that is surrounded by the substrate 151, the substrate 152, and the adhesive layer 144. A polarizing plate 260a is positioned on the outer surface of the substrate 152, and a polarizing plate 260b is positioned on the outer surface of the substrate 151. Although not illustrated, a backlight can be provided outside the polarizing plate 260a or the polarizing plate 260b.

The substrate 151 is provided with the transistor 205D, the transistor 205R, the transistor 205G, the transistor 205B (not illustrated), the connection portion 204, a spacer 224, and the like. The conductive layer 112b included in each of the transistors 205R, 205G, and 205B (not illustrated) is electrically connected to a pixel electrode 111 of a liquid crystal element 60.

The substrate 152 is provided with the coloring layers 132R and 132G, the light-blocking layer 117, an insulating layer 225, and the like.

A subpixel included in the display portion 162 includes a transistor, the liquid crystal element 60, and a coloring layer. For example, a subpixel that emits red light includes the transistor 205R, the liquid crystal element 60, and the coloring layer 132R that transmits red light.

The liquid crystal element 60 includes the common electrode 115, the pixel electrode 111, and the liquid crystal 262. The common electrode 115 is provided over the insulating layer 218, and an insulating layer 214 is provided over the common electrode 115. The pixel electrode 111 is provided over the insulating layer 214.

The pixel electrode 111 and the common electrode 115 transmit visible light. That is, the display device provided with the liquid crystal element 60 can be a transmissive liquid crystal display device. For example, in the case where a backlight is provided on the substrate 151 side, light from the backlight which is polarized by the polarizing plate 260b passes through the substrate 151, the liquid crystal element 60, and the substrate 152, and then reaches the polarizing plate 260a. In this case, optical modulation of the light can be controlled by controlling the alignment of the liquid crystal 262 with a voltage applied between the pixel electrode 111 and the common electrode 115. In other words, the intensity of light emitted through the polarizing plate 260a can be controlled. Light other than one in a particular wavelength region of the incident light is absorbed by the coloring layer, and thus, extracted light is red light, for example.

Here, as the polarizing plate 260a, a linear polarizing plate may be used or a circularly polarizing plate can also be used. An example of a circularly polarizing plate is a stack including a linear polarizing plate and a quarter-wave retardation plate. Reflection of external light can be inhibited with a circularly polarizing plate used as the polarizing plate 260a.

Note that in the case where a circularly polarizing plate is used as the polarizing plate 260a, a circularly polarizing plate or a general linear polarizing plate may be used as the polarizing plate 260b. The cell gap, alignment, driving voltage, and the like of the liquid crystal element used as the liquid crystal element 60 are adjusted in accordance with the kinds of polarizing plates used as the polarizing plate 260a and the polarizing plate 260b so that desirable contrast is obtained.

The connection portion 204 is provided in a region near an end portion of the substrate 151. In the connection portion 204, the wiring 165 is electrically connected to the FPC 172 through the conductive layer 166 and the connection layer 242. The wiring 165 is connected to the wiring 165 through an opening provided in an insulating layer. In the structure example illustrated in FIG. 24, the wiring 165 is formed using the same material in the same process as the conductive layer 112a and the conductive layer 107, and the conductive layer 166 is formed using the same material in the same process as the conductive layer 112b.

In a plan view, the pixel electrode 111 has a comb-like shape or a shape with a slit (a vertically or horizontally oriented opening). The pixel electrode 111 is provided to overlap with the common electrode 115. There is a portion where the pixel electrode 111 is not provided over the common electrode 115 in a region overlapping with the coloring layer.

Note that in the liquid crystal element 60, both the pixel electrode 111 and the common electrode 115 may have comb-like top surface shapes. Meanwhile, as in the display device 100D, only one of the pixel electrode 111 and the common electrode 115 in the liquid crystal element 60 has a comb-like top surface shape, whereby the pixel electrode 111 and the common electrode 115 partly overlap with each other. This allows capacitance between the pixel electrode 111 and the common electrode 115 to be used as a storage capacitance, and thus another capacitor does not need to be provided. Accordingly, the aperture ratio of the display device can be increased.

The insulating layer 225 is provided on the substrate 152 side to cover the coloring layers 132R and 132G and the light-blocking layer 117. The insulating layer 225 functions as an overcoat that prevents diffusion of components contained in the coloring layers 132R and 132G and the like into the liquid crystal 262. The insulating layer 225 may have a function of a planarization film. The insulating layer 225 can be formed using a light-transmitting organic resin.

Alignment films for controlling the alignment of the liquid crystal 262 may be provided on surfaces of the pixel electrode 111, the insulating layer 214, the insulating layer 225, and the like which are in contact with the liquid crystal 262.

The above is the description of the structure example of the display device.

### Manufacturing Method Example of Display Device

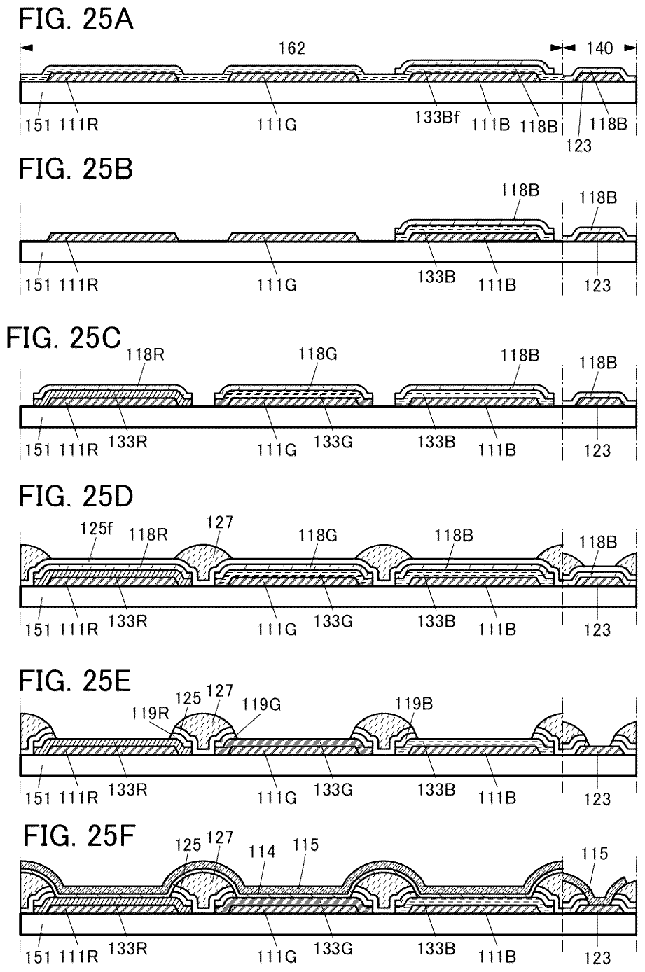

A method for manufacturing a display device having an MML (metal maskless) structure will be described below. Here, processes of manufacturing light-emitting elements without using a fine metal mask will be described in detail. In FIG. 25, cross-sectional views of three light-emitting elements included in the display portion 162 and the connection portion 140 in the manufacturing steps are illustrated.

For manufacture of the light-emitting elements, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure printing method, or a micro-contact printing method).

In the method described below for manufacturing the display device, the island-shaped layer (the layer including the light-emitting layer) is formed not by using a fine metal mask but by forming a light-emitting layer on the entire surface and processing the light-emitting layer by a photolithography method. Accordingly, a high-resolution display device or a display device with a high aperture ratio, which has been difficult to be formed so far, can be obtained. Moreover, light-emitting layers can be formed separately for the respective colors, enabling the display device to perform extremely clear display with high contrast and high display quality. Moreover, providing a sacrificial layer over the light-emitting layer can reduce damage to the light-emitting layer in the manufacturing process of the display device, resulting in an increase in reliability of the light-emitting element.

For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by repeating formation of a light-emitting layer and processing by photolithography three times.

First, the pixel electrodes 111R, 111G, and 111B and the conductive layer 123 are formed over the substrate 151 provided with the transistors 205R, 205G, and 205B (not illustrated) and the like (FIG. 25A).

A conductive film to be the pixel electrodes can be formed by a sputtering method or a vacuum evaporation method, for example. A resist mask is formed over the conductive film by a photolithography process, and then the conductive film is processed, whereby the pixel electrodes 111R, 111G, and 111B and the conductive layer 123 can be formed. For the processing of the conductive film, a wet etching method and/or a dry etching method can be used.

Next, a film 133Bf to be the layer 133B later is formed over the pixel electrodes 111R, 111G, and 111B (FIG. 25A). The film 133Bf (to be the layer 133B later) includes a light-emitting layer that emits blue light.

In an example described in this embodiment, an island-shaped EL layer included in the light-emitting element that emits blue light is formed first, and then island-shaped EL layers included in the light-emitting elements that emit light of the other colors are formed.

In the formation process of the island-shaped EL layers, the pixel electrode of the light-emitting element of the color formed second or later is sometimes damaged by the preceding process. In this case, the driving voltage of the light-emitting element of the color formed second or later might be high.

In view of this, in manufacture of the display device of one embodiment of the present invention, it is preferable that an island-shaped EL layer of a light-emitting element that emits light with the shortest wavelength (e.g., the blue-light-emitting element) be formed first. For example, it is preferable that the island-shaped EL layers be formed for the blue-, green-, and red-light-emitting elements in this order or the blue-, red-, and green-light-emitting elements in this order.

This enables the blue-light-emitting element to keep the favorable state of the interface between the pixel electrode and the EL layer and to be inhibited from having an increased driving voltage. In addition, the blue-light-emitting element can have a longer lifetime and higher reliability. Note that the red-light-emitting element and the green-light-emitting element have a smaller increase in driving voltage or the like than the blue-light-emitting element, resulting in a lower driving voltage and higher reliability of the whole display device.

Note that the formation order of the island-shaped EL layers is not limited to the above; for example, the island-shaped EL layers may be formed for the red-, green-, and blue-light-emitting elements in this order.

As illustrated in FIG. 25A, the film 133Bf is not formed over the conductive layer 123. The film 133Bf can be formed only in a desired region using an area mask, for example. Employing a film formation process using an area mask and a processing process using a resist mask enables a light-emitting element to be manufactured by a relatively easy process.

The heat resistance temperature of the compounds contained in the film 133Bf is preferably higher than or equal to 100 ° C and lower than or equal to 180 ° C, further preferably higher than or equal to 120 ° C and lower than or equal to 180 ° C, still further preferably higher than or equal to 140 ° C and lower than or equal to 180 ° C. Thus, the reliability of the light-emitting element can be increased. In addition, the upper limit of the temperature that can be applied in the manufacturing process of the display device can be increased. Therefore, the range of choices of the materials and the manufacturing method of the display device can be widened, thereby improving the manufacturing yield and the reliability.

Examples of the heat resistance temperature include the glass transition point, the softening point, the melting point, the thermal decomposition temperature, and the 5% weight loss temperature, and the lowest one among the temperatures is preferable.

The film 133Bf can be formed by an evaporation method, specifically a vacuum evaporation method, for example. The film 133Bf may be formed by a transfer method, a printing method, an inkjet method, a coating method, or the like.

Next, a sacrificial layer 118B is formed over the film 133Bf and the conductive layer 123 (FIG. 25A). A resist mask is formed over a film to be the sacrificial layer 118B by a photolithography process, and then the film is processed, whereby the sacrificial layer 118B can be formed.

Providing the sacrificial layer 118B over the film 133Bf can reduce damage to the film 133Bf in the manufacturing process of the display device, resulting in an increase in reliability of the light-emitting element.

The sacrificial layer 118B is preferably provided to cover the end portions of the pixel electrodes 111R, 111G, and 111B. Accordingly, the end portion of the layer 133B formed in a later process is positioned outward from the end portion of the pixel electrode 111B. The entire top surface of the pixel electrode 111B can be used as a light-emitting region, so that the aperture ratio of the pixel can be increased. The end portion of the layer 133B might be damaged in a process after the formation of the layer 133B, and thus is preferably positioned outward from the end portion of the pixel electrode 111B, i.e., not used as the light-emitting region. This can suppress a variation in the characteristics of the light-emitting elements and can improve reliability.

When the layer 133B covers the top surface and side surface of the pixel electrode 111B, the processes after the formation of the layer 133B can be performed without exposing the pixel electrode 111B. When the end portion of the pixel electrode 111B is exposed, corrosion might occur in the etching process or the like. When corrosion of the pixel electrode 111B is inhibited, the yield and characteristics of the light-emitting element can be improved.

The sacrificial layer 118B is preferably provided also at a position overlapping with the conductive layer 123. This can inhibit the conductive layer 123 from being damaged during the manufacturing process of the display device.

As the sacrificial layer 118B, a film that is highly resistant to the process conditions for the film 133Bf, specifically, a film having high etching selectivity with respect to the film 133Bf is used.

The sacrificial layer 118B is formed at a temperature lower than the heat resistance temperature of each compound included in the film 133Bf. The typical substrate temperature in the formation of the sacrificial layer 118B is lower than or equal to 200 ° C, preferably lower than or equal to 150 ° C, further preferably lower than or equal to 120 ° C, still further preferably lower than or equal to 100 ° C, yet still further preferably lower than or equal to 80 ° C

The heat resistance temperature of the compound included in the film 133Bf is preferably high, in which case the film formation temperature of the sacrificial layer 118B can be high. For example, the substrate temperature in formation of the sacrificial layer 118B can be higher than or equal to 100 ° C, higher than or equal to 120 ° C, or higher than or equal to 140 ° C. An inorganic insulating film formed at a higher temperature can be denser and have a better barrier property. Therefore, forming the sacrificial layer at such a temperature can further reduce damage to the film 133Bf and improve the reliability of the light-emitting element.

Note that the same can be applied to the film formation temperature of another layer formed over the film 133Bf (e.g., an insulating film 125f).

The sacrificial layer 118B can be formed by a sputtering method, an ALD method (including a thermal ALD method and a PEALD method), a CVD method, or a vacuum evaporation method, for example. Alternatively, the sacrificial layer 118B may be formed by the above-described wet process.

The sacrificial layer 118B (or a layer that is in contact with the film 133Bf in the case where the sacrificial layer 118B has a stacked-layer structure) is preferably formed by a formation method that causes less damage to the film 133Bf. For example, the sacrificial layer 118B is preferably formed by an ALD method or a vacuum evaporation method rather than a sputtering method.

The sacrificial layer 118B can be processed by a wet etching method or a dry etching method. The sacrificial layer 118B is preferably processed by anisotropic etching.

In the case of employing a wet etching method, damage to the film 133Bf in processing of the sacrificial layer 118B can be reduced as compared to the case of employing a dry etching method. In the case of employing a wet etching method, it is preferable to use a developer, a tetramethylammonium hydroxide (TMAH) aqueous solution, dilute hydrofluoric acid, oxalic acid, phosphoric acid, acetic acid, nitric acid, or a chemical solution containing a mixed solution of two or more of these acids, for example. In the case of employing a wet etching method, a mixed acid chemical solution containing water, phosphoric acid, diluted hydrofluoric acid, and nitric acid may be used. A chemical solution used for the wet etching treatment may be alkaline or acid.

As the sacrificial layer 118B, one or more of a metal film, an alloy film, a metal oxide film, a semiconductor film, an inorganic insulating film, and an organic insulating film can be used, for example.

For the sacrificial layer 118B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

The sacrificial layer 118B can be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

For example, a semiconductor material such as silicon or germanium can be used as a material with excellent compatibility with the semiconductor manufacturing process. Alternatively, an oxide or a nitride of the semiconductor material can be used. Alternatively, a non-metallic material such as carbon or a compound thereof can be used. Alternatively, a metal such as titanium, tantalum, tungsten, chromium, or aluminum, or an alloy containing one or more of these metals can be used. Alternatively, an oxide containing the above-described metal, such as titanium oxide or chromium oxide, or a nitride such as titanium nitride, chromium nitride, or tantalum nitride can be used.

For the sacrificial layer 118B, any of a variety of inorganic insulating films that can be used as the protective layer 131 can be used. In particular, an oxide insulating film is preferable because its adhesion to the film 133Bf is higher than that of a nitride insulating film. For example, an inorganic insulating material such as aluminum oxide, hafnium oxide, or silicon oxide can be used for the sacrificial layer 118B. For the sacrificial layer 118B, an aluminum oxide film can be formed by an ALD method, for example. An ALD method is preferably used, in which case damage to a base (in particular, the film 133Bf) can be reduced.

For example, a stacked-layer structure of an inorganic insulating film (e.g., an aluminum oxide film) formed by an ALD method and an inorganic film (e.g., an In—Ga—Zn oxide film, a silicon film, or a tungsten film) formed by a sputtering method can be employed for the sacrificial layer 118B.

Note that the same inorganic insulating film can be used for both the sacrificial layer 118B and the insulating layer 125 that is to be formed later. For example, an aluminum oxide film formed by an ALD method can be used for both the sacrificial layer 118B and the insulating layer 125. For the sacrificial layer 118B and the insulating layer 125, the same film formation condition may be used or different film formation conditions may be used. For example, when the sacrificial layer 118B is formed under conditions similar to those of the insulating layer 125, the sacrificial layer 118B can be an insulating layer having a high barrier property against at least one of water and oxygen. Meanwhile, since the sacrificial layer 118B is a layer a large part or the whole of which is to be removed in a later process, it is preferable that the processing of the sacrificial layer 118B be easy. Therefore, the sacrificial layer 118B is preferably formed with a substrate temperature lower than that for formation of the insulating layer 125.

An organic material may be used for the sacrificial layer 118B. For example, as the organic material, a material that can be dissolved in a solvent chemically stable with respect to at least the uppermost film of the film 133Bf may be used. Specifically, a material that is dissolved in water or alcohol can be suitably used. In forming a film of such a material, it is preferable to apply the material dissolved in a solvent such as water or alcohol by a wet process and then perform heat treatment for evaporating the solvent. At this time, the heat treatment is preferably performed under a reduced-pressure atmosphere, in which case the solvent can be removed at a low temperature in a short time and thermal damage to the film 133Bf can be accordingly reduced.

The sacrificial layer 118B may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin like perfluoropolymer.

For example, a stacked-layer structure of an organic film (e.g., a PVA film) formed by an evaporation method or the above wet process, and an inorganic film (e.g., a silicon nitride film) formed by a sputtering method can be employed for the sacrificial layer 118B.

Note that in the display device of one embodiment of the present invention, part of the sacrificial film remains as the sacrificial layer in some cases.

Then, the film 133Bf is processed using the sacrificial layer 118B as a hard mask, so that the layer 133B is formed (FIG. 25B).

Accordingly, as illustrated in FIG. 25B, the stacked-layer structure of the layer 133B and the sacrificial layer 118B remains over the pixel electrode 111B. In addition, the pixel electrode 111R and the pixel electrode 111G are exposed. In a region corresponding to the connection portion 140, the sacrificial layer 118B remains over the conductive layer 123.

The film 133Bf is preferably processed by anisotropic etching. Anisotropic dry etching is particularly preferable. Alternatively, wet etching may be employed.

After that, steps similar to the formation step of the film 133Bf, the formation step of the sacrificial layer 118B, and the formation step of the layer 133B are repeated twice under the condition where at least light-emitting substances are changed, whereby a stacked-layer structure of the layer 133R and a sacrificial layer 118R is formed over the pixel electrode 111R and a stacked-layer structure of the layer 133G and a sacrificial layer 118G is formed over the pixel electrode 111G (FIG. 25C). Specifically, the layer 133R is formed to include a light-emitting layer that emits red light, and the layer 133G is formed to include a light-emitting layer that emits green light. The sacrificial layers 118R and 118G can be formed using a material that can be used for the sacrificial layer 118B. The sacrificial layers 118R and 118G may be formed using the same material or different materials.

Note that the side surfaces of the layer 133B, the layer 133G, and the layer 133R are preferably perpendicular or substantially perpendicular to their formation surfaces. For example, the angle between the formation surfaces and these side surfaces is preferably greater than or equal to 60° and less than or equal to 90°.

As described above, the distance between two adjacent layers among the layer 133B, the layer 133G, and the layer 133R formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between opposite end portions of two adjacent layers among the layer 133B, the layer 133G, and the layer 133R. When the distance between the island-shaped EL layers is shortened in this manner, a high-resolution display device with a high aperture ratio can be provided.

Next, the insulating film 125f to be the insulating layer 125 later is formed to cover the pixel electrodes, the layer 133B, the layer 133G, the layer 133R, the sacrificial layer 118B, the sacrificial layer 118G, and the sacrificial layer 118R, and then the insulating layer 127 is formed over the insulating film 125f (FIG. 25D).

As the insulating film 125f, an insulating film having a thickness greater than or equal to 3 nm and less than or equal to 200 nm is preferably formed, for example. More specifically, the insulating film 125f is preferably formed to have a thickness greater than or equal to 3 nm, greater than or equal to 5 nm, or greater than or equal to 10 nm, and less than or equal to 200 nm, less than or equal to 150 nm, less than or equal to 100 nm, or less than or equal to 50 nm.

The insulating film 125f is preferably formed by an ALD method, for example. An ALD method is preferably used, in which case damage during film formation is reduced and a film with good coverage can be formed. As the insulating film 125f, an aluminum oxide film is preferably formed by an ALD method, for example.

Alternatively, the insulating film 125f may be formed by a sputtering method, a CVD method, or a plasma CVD method that provides a higher film formation rate than an ALD method. In this case, a highly reliable display device can be manufactured with high productivity.

For example, the insulating film to be the insulating layer 127 is preferably formed by the aforementioned wet process (e.g., spin coating) using a photosensitive resin composite containing an acrylic resin. After the formation, heat treatment (also referred to as pre-baking) is preferably performed to eliminate a solvent contained in the insulating film. Next, part of the insulating film is irradiated with visible light or ultraviolet rays as light exposure. Next, the region of the insulating film exposed to light is removed by development. Then, heat treatment (also referred to as post-baking) is performed. Accordingly, the insulating layer 127 illustrated in FIG. 25D can be formed. Note that the shape of the insulating layer 127 is not limited to the shape illustrated in FIG. 25D. For example, the top surface of the insulating layer 127 can include one or more of a convex surface, a concave surface, and a flat surface. The insulating layer 127 may cover the side surface of an end portion of at least one of the insulating layer 125, the sacrificial layer 118B, the sacrificial layer 118G, and the sacrificial layer 118R.

Next, as illustrated in FIG. 25E, etching treatment is performed using the insulating layer 127 as a mask to remove the insulating film 125f and parts of the sacrificial layers 118B, 118G, and 118R. Consequently, openings are formed in the sacrificial layers 118B, 118G, and 118R, and the top surfaces of the layer 133G, the layer 133G, the layer 133R, and the conductive layer 123 are exposed. Note that portions of the sacrificial layers 118B, 118G, and 118R may remain in positions overlapping with the insulating layer 127 and the insulating layer 125 (see sacrificial layers 119B, 119G, and 119R).

The etching treatment can be performed by dry etching or wet etching. Note that the insulating film 125f is preferably formed using a material similar to that for the sacrificial layers 118B, 118G, and 118R, in which case etching treatment can be performed collectively.

As described above, by providing the insulating layer 127, the insulating layer 125, the sacrificial layer 118B, the sacrificial layer 118G, and the sacrificial layer 118R, poor connection due to a disconnected portion and an increase in electric resistance due to a locally thinned portion can be inhibited from occurring in the common layer 114 and the common electrode 115 between the light-emitting elements. Thus, the display device of one embodiment of the present invention can have improved display quality.

Next, the common layer 114 and the common electrode 115 are formed in this order over the insulating layer 127, the layer 133B, the layer 133G, and the layer 133R (FIG. 25F).

The common layer 114 can be formed by an evaporation method (including a vacuum evaporation method), a transfer method, a printing method, an inkjet method, a coating method, or the like.

The common electrode 115 can be formed by a sputtering method or a vacuum evaporation method, for example. Alternatively, a film formed by an evaporation method and a film formed by a sputtering method may be stacked.

As described above, in the method for manufacturing the display device of one embodiment of the present invention, the island-shaped layer 133B, the island-shaped layer 133G, and the island-shaped layer 133R are formed not by using a fine metal mask but by forming a film on the entire surface and processing the film; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the layer 133B, the layer 133G, and the layer 133R can be inhibited from being in contact with each other in the adjacent subpixels. As a result, generation of a leakage current between the subpixels can be inhibited. This can prevent unintended light emission due to crosstalk, so that a display device with extremely high contrast can be obtained.

The insulating layer 127 having a tapered end portion and being provided between adjacent island-shaped EL layers can prevent step disconnection and a locally thinned portion to be formed in the common electrode 115 at the time of forming the common electrode 115. Thus, poor connection due to a disconnected portion and an increase in electric resistance due to a locally thinned portion can be inhibited from occurring in the common layer 114 and the common electrode 115. Hence, the display device of one embodiment of the present invention achieves both high resolution and high display quality.

The above is the description of the example of the method for manufacturing the display device.

At least part of the structure examples, the drawings corresponding thereto, and the like described in this embodiment can be combined with the other structure examples, the other drawings, and the like as appropriate.

### Embodiment 3

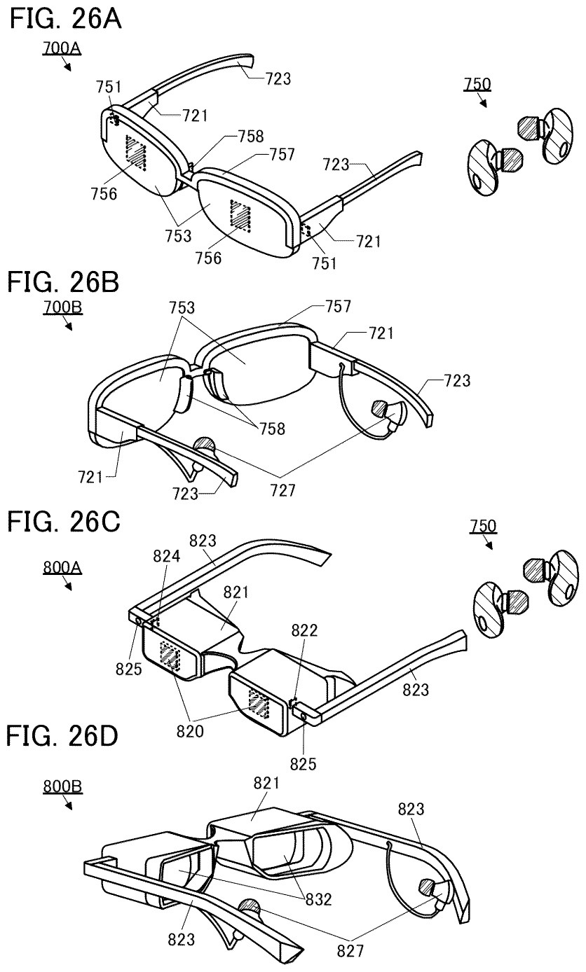

In this embodiment, electronic devices of one embodiment of the present invention will be described with reference to FIG. 26 to FIG. 28.

Electronic devices in this embodiment each include the display device of one embodiment of the present invention in a display portion. The display device of one embodiment of the present invention can be easily increased in resolution and definition. Thus, the display device of one embodiment of the present invention can be used for a display portion of a variety of electronic devices.

A semiconductor device of one embodiment of the present invention can also be applied to any other portion of an electronic device than a display portion. For example, the semiconductor device of one embodiment of the present invention is preferably used for a control portion or the like of an electronic device to enable lower power consumption.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have a high resolution, and thus can be favorably used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and a device for MR (Mixed Reality).

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably 100 ppi or higher, further preferably 300 ppi or higher, still further preferably 500 ppi or higher, yet still further preferably 1000 ppi or higher, yet still further preferably 2000 ppi or higher, yet still further preferably 3000 ppi or higher, yet still further preferably 5000 ppi or higher, yet still further preferably 7000 ppi or higher. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices that can be worn on a head are described using FIG. 26A to FIG. 26D. The wearable devices have at least one of a function of displaying AR contents, a function of displaying VR contents, a function of displaying SR contents, and a function of displaying MR contents. The electronic device having a function of displaying contents of at least one of AR, VR, SR (Substitutional Reality), MR, and the like enables the user to feel a higher level of immersion.

An electronic device 700A illustrated in FIG. 26A and an electronic device 700B illustrated in FIG. 26B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are each provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 26C and an electronic device 800B illustrated in FIG. 26D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic devices are capable of performing ultrahigh-resolution display. Such electronic devices provide a high sense of immersion to the user.

The display portions 820 are positioned inside the housing 821 so as to be seen through the lenses 832. When the pair of display portions 820 display different images, three-dimensional display using parallax can be performed.

Each of the electronic device 800A and the electronic device 800B can be regarded as an electronic device for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lenses 832 and the display portions 820 is preferably included.

The electronic device 800A or the electronic device 800B can be mounted on the user's head with the wearing portions 823. FIG. 26C and the like illustrate examples where the wearing portion has a shape like a temple of glasses; however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Note that although an example where the image capturing portion 825 is included is illustrated here, a range sensor that is capable of measuring the distance to an object (hereinafter such a sensor is also referred to as a sensing portion) is provided. In other words, the image capturing portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more pieces of information can be obtained and a gesture operation with higher accuracy is possible.

The electronic device 800A may include a vibration mechanism that functions as a bone-conduction earphone. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic device 800A and the electronic device 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 26A has a function of transmitting information to the earphones 750 with the wireless communication function. As another example, the electronic device 800A illustrated in FIG. 26C has a function of transmitting information to the earphones 750 with the wireless communication function.

The electronic device may include an earphone portion. The electronic device 700B illustrated in FIG. 26B includes earphone portions 727. For example, the earphone portions 727 can be connected to the control portion by wire. Part of a wiring that connects the earphone portions 727 and the control portion may be positioned inside the housing 721 or the wearing portion 723.

Similarly, the electronic device 800B illustrated in FIG. 26D includes earphone portions 827. For example, the earphone portions 827 can be connected to the control portion 824 by wire. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (the electronic device 700A, the electronic device 700B, or the like) and the goggles-type device (the electronic device 800A, the electronic device 800B, or the like) are suitable as the electronic device of one embodiment of the present invention.

The electronic device of one embodiment of the present invention can transmit information to earphones by wire or wirelessly.

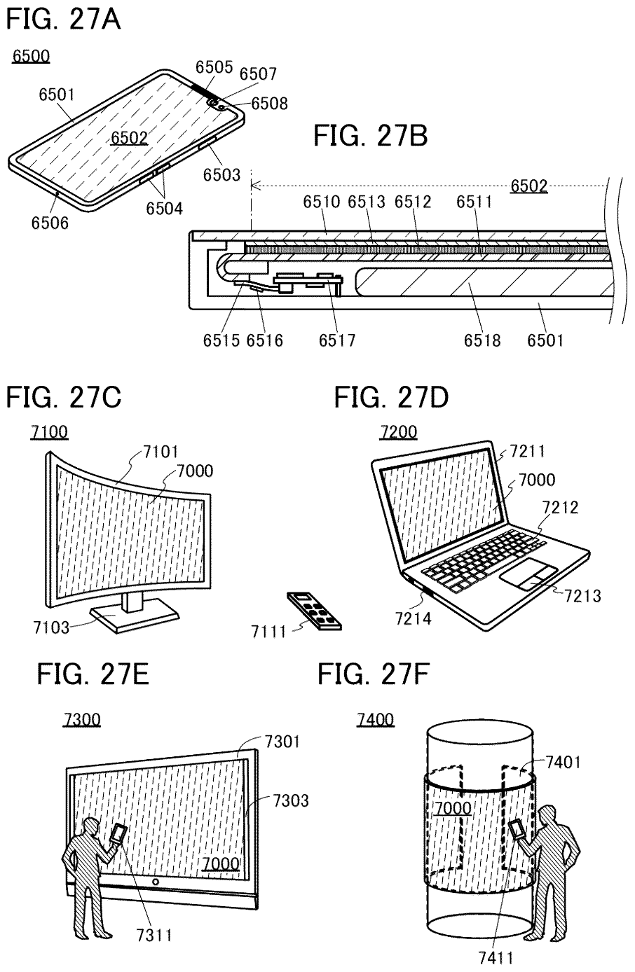

An electronic device 6500 illustrated in FIG. 27A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 27B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A display device of one embodiment of the present invention can be used for the display panel 6511. In that case, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 27C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operations of the television device 7100 illustrated in FIG. 27C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 27D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIG. 27E and FIG. 27F illustrate examples of digital signage.

Digital signage 7300 illustrated in FIG. 27E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 27F is digital signage 7400 attached to a cylindrical pillar 7401. The digital signage 7400 includes the display portion 7000 provided along a curved surface of the pillar 7401.

The display device of one embodiment of the present invention can be used for the display portion 7000 in each of FIG. 27E and FIG. 27F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by the user is possible in addition to display of an image or a moving image on the display portion 7000. Moreover, for an application for providing information such as route information or traffic information, usability can be enhanced by intuitive operation.

As illustrated in FIG. 27E and FIG. 27F, it is preferable that the digital signage 7300 or the digital signage 7400 can work with an information terminal 7311 or an information terminal 7411 such as a smartphone the user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

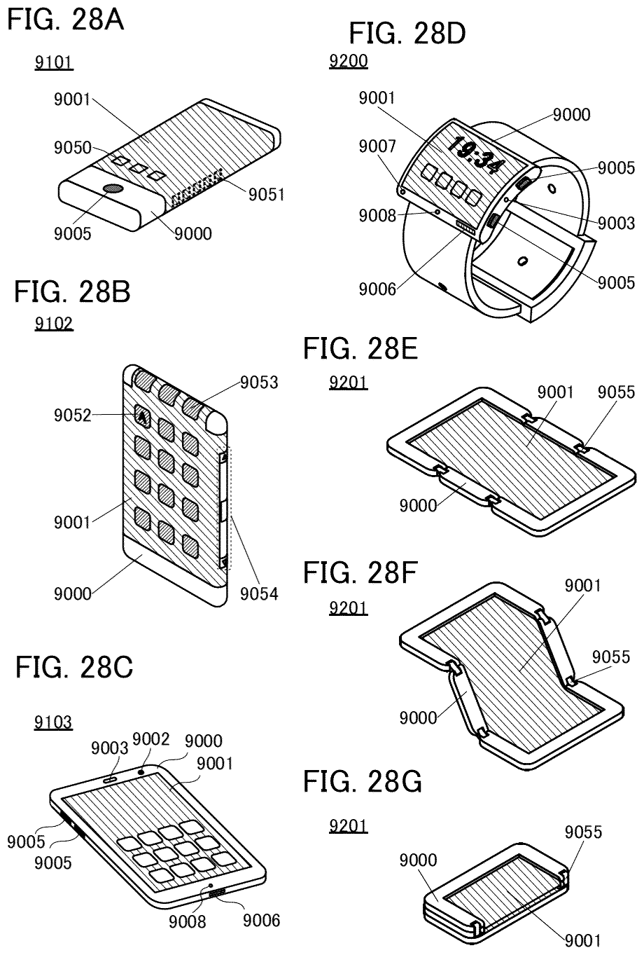

Electronic devices illustrated in FIG. 28A to FIG. 28G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays), a microphone 9008, and the like.

The display device of one embodiment of the present invention can be used for the display portion 9001 in FIG. 28A to FIG. 28G.

The electronic devices illustrated in FIG. 28A to FIG. 28G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices illustrated in FIG. 28A to FIG. 28G are described in detail below.

FIG. 28A is a perspective view illustrating a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 28A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 28B is a perspective view illustrating a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 28C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 28D is a perspective view illustrating a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 28E to FIG. 28G are perspective views illustrating a foldable portable information terminal 9201. In addition, FIG. 28E is a perspective view of an opened state of the portable information terminal 9201, FIG. 28G is a perspective view of a folded state thereof, and FIG. 28F is a perspective view of a state in the middle of change from one of FIG. 28E and FIG. 28G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

At least part of the structure examples, the drawings corresponding thereto, and the like described in this embodiment can be combined with the other structure examples, the other drawings, and the like as appropriate.

### REFERENCE NUMERALS

10a: transistor, 10b: transistor, 11: insulating layer, 12a: side surface, 12b: side surface, 12c: side surface, 20a: slit, 20b: slit, 20C: opening, 20: slit, 21A: semiconductor layer, 21a: semiconductor layer, 21B: semiconductor layer, 21b: semiconductor layer, 21: semiconductor layer, 22A: insulating layer, 22B: insulating layer, 22: insulating layer, 23a: conductive layer, 23b: conductive layer, 23: conductive layer, 24a: conductive layer, 24b: conductive layer, 24d: conductive layer, 24: conductive layer, 25a: conductive layer, 25ad: conductive layer, 25b: conductive layer, 25bd: conductive layer, 25: conductive layer, 26: conductive layer, 27: insulating layer, 31: conductive layer, 32: conductive layer, 33: conductive layer, 34: conductive layer, 41a: insulating layer, 41b: insulating layer, 41c: insulating layer, 41: insulating layer, 42: insulating layer, 43: insulating layer, 44: insulating layer, 45: insulating layer, 24: conductive layer, 25a: conductive layer, 25b: conductive layer, 25: conductive layer, 26: conductive layer, 27: insulating layer, 31: conductive layer, 32: conductive layer, 33: conductive layer, 34: conductive layer, 41a: insulating layer, 41b: insulating layer, 41c: insulating layer, 41: insulating layer, 42: insulating layer, 43: insulating layer, 44: insulating layer, 45: insulating layer, 46: insulating layer, 50s: subpixel, 50: pixel, 50: pixel, 51: conductive layer, 52: conductive layer, 53: conductive layer, 54: conductive layer, 55: conductive layer, 56: conductive layer, 57: conductive layer, 58: conductive layer, 60: liquid crystal element, 61: conductive layer, 62: conductive layer, 51: conductive layer, 52: conductive layer, 53: conductive layer, 54: conductive layer, 55: conductive layer, 56: conductive layer, 57: conductive layer, 58: conductive layer, 60: liquid crystal element, 61: conductive layer, 62: conductive layer, 100A: display device, 100B: display device, 100C: display device, 100D: display device, 104: conductive layer, 106: insulating layer, 107: conductive layer, 108: semiconductor layer, 109: conductive layer, 110: insulating layer, 111B: pixel electrode, 111G: pixel electrode, 111R: pixel electrode, 111: pixel electrode, 112a: conductive layer, 112b: conductive layer, 113B: EL layer, 113G: EL layer, 113R: EL layer, 113: EL layer, 114: common layer, 115: common electrode, 117: light-blocking layer, 118B: sacrificial layer, 118G: sacrificial layer, 118R: sacrificial layer, 119B: sacrificial layer, 119G: sacrificial layer, 123: conductive layer, 124B: conductive layer, 124G: conductive layer, 124R: conductive layer, 125f: insulating film, 125: insulating layer, 126B: conductive layer, 126G: conductive layer, 126R: conductive layer, 127: insulating layer, 128: layer, 130B: light-emitting element, 130G: light-emitting element, 130R: light-emitting element, 131: protective layer, 132B: coloring layer, 132G: coloring layer, 132R: coloring layer, 133B: layer, 133Bf: film, 133G: layer, 133R: layer, 140: connection portion, 142: adhesive layer, 144: adhesive layer, 151: substrate, 152: substrate, 153: insulating layer, 162: display portion, 164: circuit portion, 165: wiring, 166: conductive layer, 172: FPC, 173: IC, 204: connection portion, 205B: transistor, 205D: transistor, 205G: transistor, 205R: transistor, 210B: subpixel, 210G: subpixel, 210R: subpixel, 210: pixel, 214: insulating layer, 218: insulating layer, 224: spacer, 225: insulating layer, 235: insulating layer, 237: insulating layer, 242: connection layer, 260a: polarizing plate, 260b: polarizing plate, 262: liquid crystal

1. A semiconductor device comprising:
an insulating layer comprising a side surface; and
a first transistor and a second transistor each comprising one of a source electrode and a drain electrode over the insulating layer and the other of the source electrode and the drain electrode below the insulating layer,
wherein semiconductor layers of the first transistor and the second transistor are each in contact with the side surface of the insulating layer, and
wherein a gate insulating layer shared by the first transistor and the second transistor is in contact with the two semiconductor layers and the side surface of the insulating layer.

2. A semiconductor device comprising:
a first transistor, a second transistor, and an insulating layer,
wherein the insulating layer comprises a first side surface and a second side surface facing the first side surface,
wherein the first transistor comprises a first conductive layer, a second conductive layer, a first semiconductor layer, a gate insulating layer, and a first gate electrode,
wherein the second transistor comprises a third conductive layer, a fourth conductive layer, a second semiconductor layer, the gate insulating layer, and a second gate electrode,
wherein the first side surface of the insulating layer is positioned over the first conductive layer and the third conductive layer,
wherein the second conductive layer and the fourth conductive layer are positioned over the insulating layer,
wherein the first semiconductor layer is in contact with the first conductive layer, the second conductive layer, and the first side surface,
wherein the second semiconductor layer is in contact with the third conductive layer, the fourth conductive layer, and the first side surface,
wherein the gate insulating layer is in contact with the first semiconductor layer, the second semiconductor layer, the first side surface, and the second side surface,
wherein the first gate electrode comprises a portion overlapping with the first semiconductor layer with the gate insulating layer therebetween, and
wherein the second gate electrode comprises a portion overlapping with the second semiconductor layer with the gate insulating layer therebetween.

3. A semiconductor device comprising:
a first transistor, a second transistor, and an insulating layer,
wherein the insulating layer comprises a first side surface and a second side surface facing the first side surface,
wherein the first transistor comprises a first conductive layer, a second conductive layer, a first semiconductor layer, a gate insulating layer, and a gate electrode,
wherein the second transistor comprises a third conductive layer, a fourth conductive layer, a second semiconductor layer, the gate insulating layer, and the gate electrode,
wherein the first side surface of the insulating layer is positioned over the first conductive layer and the third conductive layer,
wherein the second conductive layer and the fourth conductive layer are positioned over the insulating layer,
wherein the first semiconductor layer is in contact with the first conductive layer, the second conductive layer, and the first side surface,
wherein the second semiconductor layer is in contact with the third conductive layer, the fourth conductive layer, and the second side surface,
wherein the gate insulating layer is in contact with the first semiconductor layer, the second semiconductor layer, the first side surface, and the second side surface,
wherein the gate electrode comprises a portion overlapping with the first semiconductor layer with the gate insulating layer therebetween and a portion overlapping with the second semiconductor layer with the gate insulating layer therebetween.

4. The semiconductor device according to claim 2,
wherein the first semiconductor layer and the second semiconductor layer each comprise a first metal oxide, and
wherein a portion of the first conductive layer that is in contact with the first semiconductor layer and a portion of the third conductive layer that is in contact with the second semiconductor layer comprise a second metal oxide.

5. The semiconductor device according to claim 2,
wherein the first semiconductor layer and the second semiconductor layer each comprise a first metal oxide, and
wherein a portion of the second conductive layer that is in contact with the first semiconductor layer and a portion of the fourth conductive layer that is in contact with the second semiconductor layer comprise a third metal oxide.

6. The semiconductor device according to claim 2,
wherein the first semiconductor layer and the second semiconductor layer each comprise a metal oxide,
wherein a first insulating film, a second insulating film, and a third insulating film are stacked in this order in the insulating layer,
wherein the first insulating film and the third insulating film comprise a nitride, and
wherein the second insulating film comprises an oxide.

7. The semiconductor device according to claim 6,
wherein the first insulating film and the third insulating film comprise silicon nitride, and
wherein the second insulating film comprises silicon oxide.

8. The semiconductor device according to claim 2,
wherein an angle formed between a bottom surface of the insulating layer and the first side surface is greater than or equal to 75° and less than or equal to 90°.

9. A display device comprising:
the semiconductor device according to claim 1, a first display element, and a second display element,
wherein the first display element is electrically connected to the first transistor, and
wherein the second display element is electrically connected to the second transistor.

10. The display device according to claim 9, further comprising a plurality of the first display elements,
wherein the first display elements are arranged with a density higher than or equal to 3000 ppi.

11. The semiconductor device according to claim 3,
wherein the first semiconductor layer and the second semiconductor layer each comprise a first metal oxide, and
wherein a portion of the first conductive layer that is in contact with the first semiconductor layer and a portion of the third conductive layer that is in contact with the second semiconductor layer comprise a second metal oxide.

12. The semiconductor device according to claim 3,
wherein the first semiconductor layer and the second semiconductor layer each comprise a first metal oxide, and
wherein a portion of the second conductive layer that is in contact with the first semiconductor layer and a portion of the fourth conductive layer that is in contact with the second semiconductor layer comprise a third metal oxide.

13. The semiconductor device according to claim 3,
wherein the first semiconductor layer and the second semiconductor layer each comprise a metal oxide,
wherein a first insulating film, a second insulating film, and a third insulating film are stacked in this order in the insulating layer,
wherein the first insulating film and the third insulating film comprise a nitride, and
wherein the second insulating film comprises an oxide.

14. The semiconductor device according to claim 13,
wherein the first insulating film and the third insulating film comprise silicon nitride, and
wherein the second insulating film comprises silicon oxide.

15. The semiconductor device according to claim 3,
wherein an angle formed between a bottom surface of the insulating layer and the first side surface is greater than or equal to 75° and less than or equal to 90°.

16. A display device comprising:
the semiconductor device according to claim 2, a first display element, and a second display element,
wherein the first display element is electrically connected to the first transistor, and
wherein the second display element is electrically connected to the second transistor.

17. The display device according to claim 16, further comprising a plurality of the first display elements,
wherein the first display elements are arranged with a density higher than or equal to 3000 ppi.

18. A display device comprising:
the semiconductor device according to claim 3, a first display element, and a second display element,
wherein the first display element is electrically connected to the first transistor, and
wherein the second display element is electrically connected to the second transistor.

19. The display device according to claim 18, further comprising a plurality of the first display elements,
wherein the first display elements are arranged with a density higher than or equal to 3000 ppi.
